(19) United States
(12) Patent Application Publication
(10) Pub. No.: US 2026/0173715 A1
(43) Pub. Date: Jun. 18, 2026

(54) DISPLAY DEVICE

(71) Applicant: Magnolia White Corporation, Tokyo (JP)

(72) Inventors: Yozo NAKAYASU, Tokyo (JP); Sho YANAGISAWA, Tokyo (JP); Ryota TAKASAKI, Tokyo (JP)

(73) Assignee: Magnolia White Corporation, Tokyo (JP)

(21) Appl. No.: 19/419,175

(22) Filed: Dec. 15, 2025

(30) Foreign Application Priority Data
Dec. 16, 2024 (JP) 2024-220111

(51) Int. Cl. H10K 59/80; H10K 59/12; H10K 59/88

(52) U.S. Cl. CPC H10K 59/871; H10K 59/1201; H10K 59/88

(57) ABSTRACT

According to one embodiment, a display device includes a display area, a dummy pixel area which includes a plurality of dummy pixels each including a first dummy subpixel not displaying an image, an outer circumferential, a partition provided in the display area, the dummy pixel area, and the outer circumferential area, a first stacked film provided in the first dummy subpixel, a first sealing layer provided above the first stacked film, a second stacked film provided in the outer circumferential area, and a second sealing layer provided above the second stacked film. The partition is formed continuously from the dummy pixel area to the outer circumferential area.

### CROSS-REFERENCE TO RELATED APPLICATION

This application is based upon and claims the benefit of priority from Japanese Patent Application No. 2024-220111, filed Dec. 16, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a view showing a configuration example of a display device according to a first embodiment.

FIG. 2 is a schematic plan view showing an example of layout of subpixels constituting a pixel.

FIG. 3 is a schematic cross-sectional view showing the display device along III-III line in FIG. 2.

FIG. 4 is a schematic cross-sectional view showing another example of the display device along III-III line in FIG. 2.

FIG. 5 is a schematic plan view showing the display device according to the first embodiment.

FIG. 6 is a schematic plan view showing an enlarged area surrounded by frame VI in FIG. 5.

FIG. 7 is a schematic plan view showing a configuration of a sealing layer provided in a display area, a dummy pixel area, and an outer circumferential area.

FIG. 8 is a schematic plan view showing an enlarged area surrounded by frame VIII in FIG. 7.

FIG. 9 is a schematic cross-sectional view showing the dummy pixel area and the outer circumferential area along IX-IX line in FIG. 7.

FIG. 10 is a schematic cross-sectional view showing the dummy pixel area and the outer circumferential area along X-X line in FIG. 7.

FIG. 11 is a flowchart showing an example of a display device manufacturing method.

FIG. 12A is a schematic cross-sectional view showing a manufacturing process of the display device.

FIG. 12B is a schematic cross-sectional view showing a process following FIG. 12A.

FIG. 12C is a schematic cross-sectional view showing a process following FIG. 12B.

FIG. 12D is a schematic cross-sectional view showing a process following FIG. 12C.

FIG. 12E is a schematic cross-sectional view showing a process following FIG. 12D.

FIG. 12F is a schematic cross-sectional view showing a process following FIG. 12E.

FIG. 12G is a schematic cross-sectional view showing a process following FIG. 12F.

FIG. 12H is a schematic cross-sectional view showing a process following FIG. 12G.

FIG. 12I is a schematic cross-sectional view showing a process following FIG. 12H.

FIG. 12J is a schematic cross-sectional view showing a process following FIG. 12I.

FIG. 13 is a schematic plan view showing the display device according to a comparative example.

FIG. 14 is a schematic cross-sectional view showing the display device along XIV-XIV line in FIG. 13.

FIG. 15 is a schematic plan view showing a display device according to a second embodiment.

FIG. 16 is a schematic enlarged view showing a XVI portion in FIG. 15.

FIG. 17 is a schematic cross-sectional view showing a dummy pixel area and an outer circumferential area along XVII-XVII line in FIG. 15.

FIG. 18 is a schematic plan view showing a display device according to a third embodiment.

FIG. 19 is a schematic plan view showing an enlarged area surrounded by frame XIX in FIG. 5.

FIG. 20 is a schematic plan view showing an enlarged area surrounded by frame XX in FIG. 5.

FIG. 21 is a schematic plan view showing a display device according to a fourth embodiment.

FIG. 22 is a schematic cross-sectional view showing a dummy pixel area and an outer circumferential area along XXII-XXII line in FIG. 21.

FIG. 23 is a schematic plan view showing another example of the display device according to the fourth embodiment.

FIG. 24 is a schematic cross-sectional view showing a dummy pixel area and an outer circumferential area along XXIV-XXIV line in FIG. 23.

FIG. 25 is a schematic plan view showing an enlarged area surrounded by frame XXV in FIG. 5.

FIG. 26 is a schematic plan view showing another example of the display device.

FIG. 27 is a schematic plan view showing an enlarged area surrounded by frame XXVII in FIG. 5.

FIG. 28 is a schematic plan view showing another example of the display device.

FIG. 29 is a schematic plan view showing an enlarged area surrounded by frame XXIX in FIG. 5.

FIG. 30 is a schematic plan view showing another example of the display device.

### DETAILED DESCRIPTION

In general, according to one embodiment, a display device includes a display area including a plurality of pixels displaying an image, a dummy pixel area which includes a plurality of dummy pixels each including a first dummy subpixel not displaying an image and which surrounds the display area, an outer circumferential area surrounding the dummy pixel area, a partition provided in the display area, the dummy pixel area, and the outer circumferential area and including a conductive lower portion and an upper portion having an end portion protruding from a side surface of the lower portion, a first stacked film provided in the first dummy subpixel and including a first organic layer, a first sealing layer formed of an inorganic insulating material and provided above the first stacked film, a second stacked film provided in the outer circumferential area and including a second organic layer, and a second sealing layer formed of an inorganic insulating material and provided above the second stacked film. The partition is formed continuously from the dummy pixel area to the outer circumferential area.

According to another embodiment, a display device includes a display area including a plurality of pixels displaying an image, a dummy pixel area which includes a plurality of dummy pixels each including a first dummy subpixel and a second dummy subpixel not displaying an image and which surrounds the display area, an outer circumferential area surrounding the dummy pixel area, a partition provided in the display area, the dummy pixel area, and the outer circumferential area and including a conductive lower portion and an upper portion having an end portion protruding from a side surface of the lower portion, a first stacked film provided in the first dummy subpixel and including a first organic layer, a first sealing layer formed of an inorganic insulating material and provided above the first stacked film, a second stacked film provided in the second dummy subpixel and including a second organic layer including a light emitting layer different from a light emitting layer of the first organic layer, and a second sealing layer formed of an inorganic insulating material and provided above the second stacked film.

The partition is formed continuously from the dummy pixel area to the outer circumferential area. The outer circumferential area includes a first area surrounding the dummy pixel area, and a second area provided between the first area and the dummy pixel area. The second sealing layer is further provided in the first area. The first sealing layer is further provided in the second area. The first sealing layer provided in the second area is in contact with the second sealing layer provided in the first area, above the partition located between the first area and the second area.

According this configuration, a display device capable of improving the yield can be improved.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

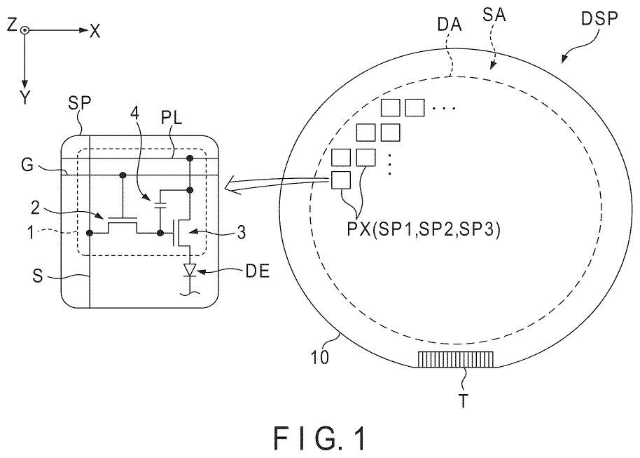

FIG. 1 is a view showing a configuration example of a display device DSP according to the present embodiment. The display device DSP comprises an insulating substrate 10. The substrate 10 has a display area DA where images are displayed, and a surrounding area SA around the display area DA. The substrate 10 may be glass or a resinous film having flexibility.

In the present embodiment, the substrate 10 and the display area DA have a circular shape in plan view. However, the shape of the substrate 10 and the display area DA in plan view is not limited to a circle, but may be the other shape such as a rectangle, a square, or an oval.

The display area DA includes a plurality of pixels PX arrayed in matrix in the first direction X and the second direction Y. Each pixel includes a plurality of subpixels SP which display different colors. This embodiment assumes a case where each pixel PX includes a blue subpixel SP1, a green subpixel SP2, and a red subpixel SP3. Each pixel PX may include a subpixel SP which displays the other color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit which applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. Each of the pixel switch 2 and the drive transistor 3 is, for example, a switching element consisting of a thin-film transistor.

A plurality of scanning lines G which supply a scanning signal to the pixel circuits 1 of the subpixels SP, a plurality of signal lines S which supply a video signal to the pixel circuits 1 of the subpixels SP and a plurality of power lines PL are provided in the display area DA. In the example of FIG. 1, the scanning lines G and the power lines PL extend in the first direction X, and the signal lines S extend in the second direction Y.

The gate electrode of the pixel switch 2 is connected to the scanning line G. One of a source electrode and a drain electrode of the pixel switch 2 is connected to the signal line S. The other electrode is connected to the gate electrode of the drive transistor 3 and the capacitor 4. In the drive transistor 3, one of the source electrode and the drain electrode is connected to the power line PL and the capacitor 4, and the other is connected to the display element DE.

Incidentally, the configuration of the pixel circuit 1 is not limited to the example shown in the figure. For example, the pixel circuit 1 may comprise more thin-film transistors and more capacitors.

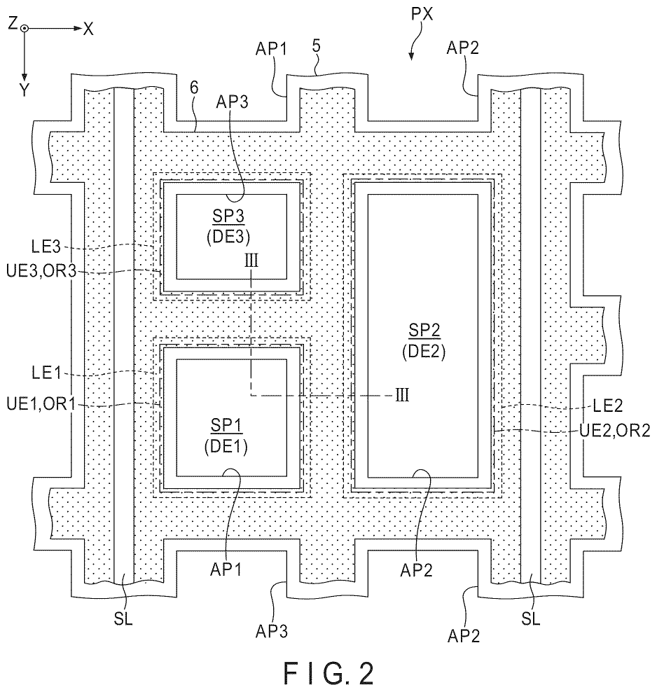

FIG. 2 is a schematic plan view showing an example of the layout of subpixels SP1, SP2, and SP3 constituting a pixel PX. In the example of FIG. 2, the subpixels SP1 and SP3 are arranged in the second direction Y. In addition, each of the subpixels SP1 and SP3 is adjacent to the subpixel SP2 in the first direction X.

When the subpixels SP1, SP2, and SP3 are provided in this layout, a column in which the subpixels SP1 and SP3 are alternately provided in the second direction Y and a column in which a plurality of subpixels SP2 are repeatedly provided in the second direction Y are formed in the display area DA. These columns are alternately arranged in the first direction X. Incidentally, the layout of the subpixels SP1, SP2, and SP3 is not limited to the example of FIG. 2.

A rib layer 5 (inorganic insulating layer) is provided in the display area DA. The rib layer 5 includes pixel apertures AP1, AP2, and AP3 in the subpixels SP1, SP2, and SP3, respectively.

In the example of FIG. 2, each of the pixel apertures AP1, AP2, and AP3 has a rectangular shape. The area of the pixel aperture AP1 is larger than that of the pixel aperture AP3. In addition, the area of the pixel aperture AP2 is larger than that of the pixel aperture AP1. The pixel aperture AP2 has a rectangular shape which is more elongated in the Y-direction than the pixel apertures AP1 and AP3. However, the shape of the pixel apertures AP1, AP2, and AP3 is not limited to this example.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

Portions of the lower electrode LE1, the upper electrode UE1, and the organic layer OR1, which overlap with the pixel aperture AP1 constitute a display element DE1 of the subpixel SP1. Portions of the lower electrode LE2, the upper electrode UE2, and the organic layer OR2, which overlap with the pixel aperture AP2 constitute a display element DE2 of the subpixel SP2. Portions of the lower electrode LE3, the upper electrode UE3, and the organic layer OR3, which overlap with the pixel aperture AP3 constitute a display element DE3 of the subpixel SP3. Each of the display elements DE1, DE2, and DE3 may further include a cap layer to be described later. The rib layer 5 surrounds each of these display elements DE1, DE2, and DE3.

A conductive partition 6 is provided above the rib layer 5. The partition 6 functions as lines which apply a common voltage to the upper electrodes UE1, UE2, and UE3. The partition 6 overlaps with the rib layer 5 as a whole and has a planar shape similar to that of the rib layer 5. The partition 6 is formed to surround the lower electrodes LE1, LE2, and LE3.

The partition 6 includes a plurality of slits SL. In the example of FIG. 2, each of the slits SL extends in the second direction Y. For example, subpixels SP1, SP2, and SP3 constituting one pixel PX is provided between two slits SL which are adjacent to each other in the first direction X.

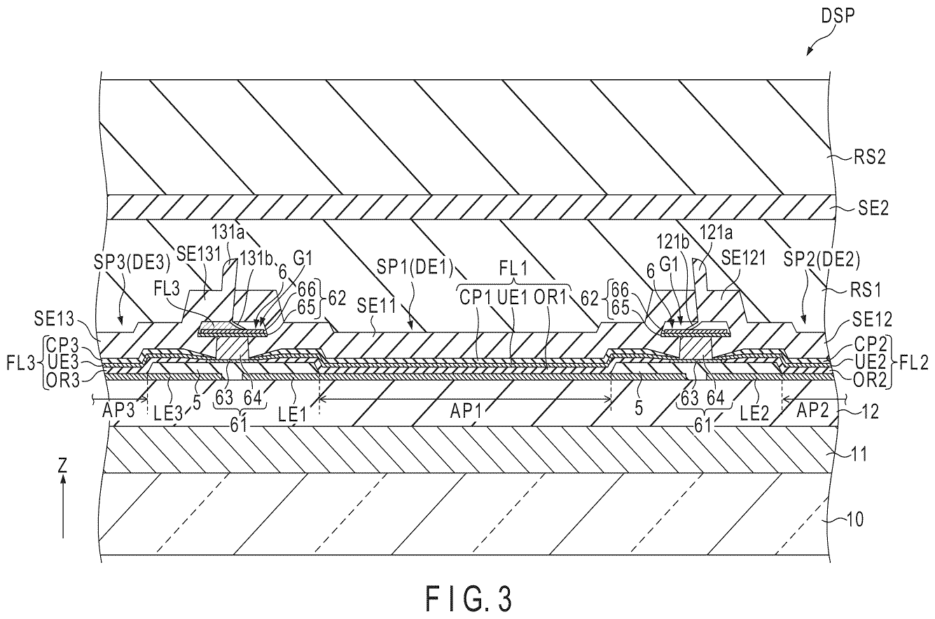

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuits 1, the scanning lines G, the signal lines S, and the power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, the lower electrodes LE1, LE2, and LE3 are connected to the respective pixel circuits 1 of the circuit layer 11 through contact holes provided in the organic insulating layer 12.

The partition 6 includes a conductive lower portion 61 provided on the rib layer 5, and an upper portion 62 provided on the lower portion 61. The upper portion 62 has a width greater than that of the lower portion 61. As a result, both end portions of the upper portion 62 protrude relative to side surfaces of the lower portion 61. This shape of the partition 6 is referred to as an overhang shape.

In the example of FIG. 3, the lower portion 61 includes a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

In addition, in the example of FIG. 3, the upper portion 62 includes a first top layer 65, and a second top layer 66 provided on the first top layer 65. For example, the width of the second top layer 66 is slightly smaller than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portion 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers which improve the efficiency of extracting the light emitted from the organic layers OR1, OR2, and OR3, respectively.

In the following descriptions, a multilayer body including the organic layer OR1, the upper electrode UE1, and the cap layer CP1 is referred to as a stacked film FL1, a multilayer body including the organic layer OR2, the upper electrode UE2, and the cap layer CP2 is referred to as a stacked film FL2, and a multilayer body including the organic layer OR3, the upper electrode UE3, and the cap layer CP3 is referred to as a stacked film FL3.

The stacked films FL1, FL2, and FL3 are provided above the lower electrodes LE1, LE2, and LE3. In addition, the rib layer 5 is provided under the partition 6 and the stacked films FL1, FL2, and FL3. Sealing layers SE11, SE12, and SE13 are provided in the subpixels SP1, SP2, and SP3, respectively.

The sealing layer SE11 continuously covers the display element DE1 including the stacked film FL1, and a partition 6 surrounding the display element DE1. The sealing layer SE12 continuously covers the display element DE2 including the stacked film FL2, and a partition 6 surrounding the display element DE2. The sealing layer SE13 continuously covers the display element DE3 including the stacked film FL1, and a partition 6 surrounding the display element DE3.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA). The electrodes which constitute the above-described touch panel may be provided on the sealing layer SE2.

In the example of FIG. 3, the end portions of the sealing layers SE11 and SE12 located on the partition 6 between the subpixels SP1 and SP2 are in contact with (closely attached to) each other. In addition, the end portions of the sealing layers SE11 and SE13 located on the partition 6 between the subpixels SP1 and SP3 are in contact with (closely attached to) each other. Furthermore, although not shown in the figure, the end portions of the sealing layers SE12 and SE13 located on the partition 6 between the subpixels SP2 and SP3 are in contact with (closely attached to) each other.

Focus on the sealing layer SE12 will be made here. The sealing layer SE12 includes an overlapping portion SE121 located above the partition 6. The overlapping portion SE121 is in contact with the end portion of the sealing layer SE11. The overlapping portion SE121 may include a protruding portion 121a that protrudes upwardly. The protruding portion 121a is located above the partition 6 between the subpixels SP1 and SP2 so as to be higher than the sealing layer SE11.

In addition, the overlapping portion SE121 may further include an extending portion 121b that extends toward a gap G1 formed between the sealing layer SE11 and the upper portion 62 of the partition 6. This gap G1 occurs due to loss of the stacked film FL1 during the manufacturing process.

The stacked film FL2 may be provided between the partition 6 and the overlapping portion SE121. Incidentally, this stacked film FL2 may be lost during the manufacturing process. In this case, a gap occurs between the sealing layer SE12 and the partition 6.

Similarly, focus on the sealing layer SE13 will be made here. The sealing layer SE13 has an overlapping portion SE131 located above the partition 6. The overlapping portion SE131 is in contact with the end portion of the sealing layer SE11. The overlapping portion SE131 may include a protruding portion 131a that protrudes upwardly. The protruding portion 131a is located above the partition 6 between the subpixels SP1 and SP3 so as to be higher than the sealing layer SE11.

In addition, the overlapping portion SE131 may further include an extending portion 131b that extends toward a gap G1 formed between the sealing layer SE11 and the upper portion 62 of the partition 6. This gap G1 occurs due to loss of the stacked film FL1 during the manufacturing process.

The stacked film FL3 may be provided between the partition 6 and the overlapping portion SE131. Incidentally, if this stacked film FL3 is lost during the manufacturing process, a gap occurs between the sealing layer SE13 and the partition 6.

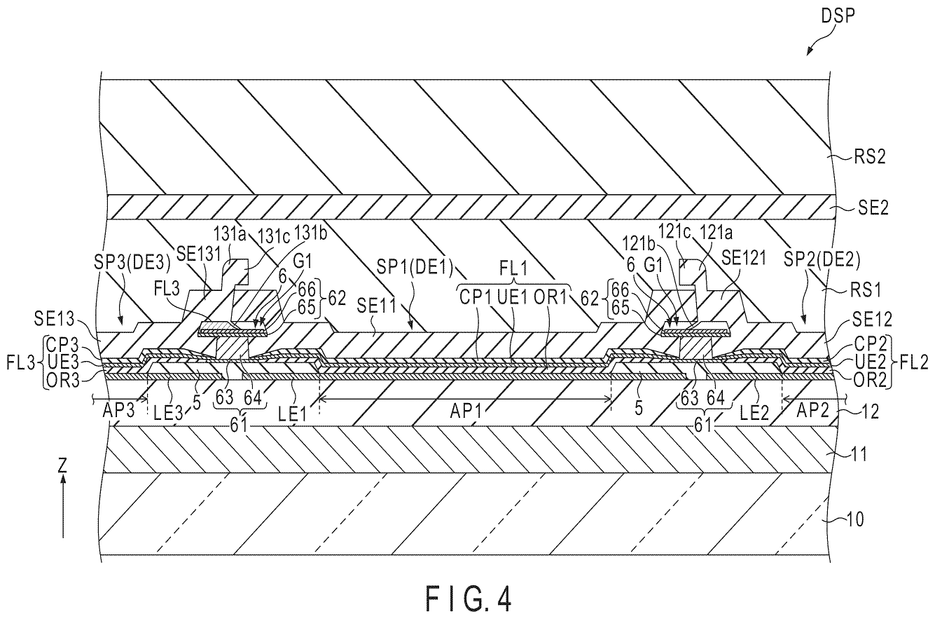

FIG. 4 is a schematic cross-sectional view showing another example of the display device DSP along III-III line in FIG. 2. In FIG. 4, the shapes of the overlapping portions SE121 and SE131 of the sealing layers SE12 and SE13 are different from those in the example shown in FIG. 3.

Focus on the sealing layer SE12 will be made here. The protruding portion 121a of the sealing layer SE12 may overlap with the sealing layer SE11. In the example of FIG. 4, the protruding portion 121a includes a portion 121c that overlaps with the sealing layer SE11. The partition 6, the sealing layer SE11, and the protruding portion 121a of the sealing layer SE12 are arranged in this order in the third direction Z. The portion 121c may or may not be in contact with the sealing layer SE11.

Similarly, focus on the sealing layer SE13 will be made here. The protruding portion 131a of the sealing layer SE13 may overlap with the sealing layer SE11. In the example of FIG. 4, the protruding portion 131a includes a portion 131c that overlaps with the sealing layer SE11. The partition 6, the sealing layer SE11, and the protruding portion 131a of the sealing layer SE13 are arranged in this order in the third direction Z. The portion 131c may or may not be in contact with the sealing layer SE11.

Although not shown in FIG. 3 or FIG. 4, focus on the area above the partition 6 between the subpixels SP2 and SP3 will be made here. The overlapping portion SE131 may include a protruding portion 131a that protrudes upwardly. The protruding portion 131a is located above the sealing layer SE12. In addition, in the example of FIG. 4, the partition 6, the sealing layer SE12, and the protrusion 131a of the sealing layer SE13 are provided above the partition 6 between the subpixels SP2 and SP3 and arranged in this order in the third direction Z.

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx), or silicon oxynitride (SiON). In one example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 includes a reflective layer formed of, for example, silver, and a pair of conductive oxide layers covering upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. The light emitting layers included in the organic layers OR1, OR2, OR3 are different from each other. In one example, each of the organic layers OR1, OR2, and OR3 has a structure in which a hole injection layer, a hole transport layer, an electron blocking layer, a light emitting layer, a hole blocking layer, an electron transport layer, and an electron injection layer are stacked in order in the third direction Z. However, each of the organic layers OR1, OR2, and OR3 may have the other structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, the transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

The bottom layer 63 and the stem layer 64 of the partition 6 are formed of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. Incidentally, the stem layer 64 may be formed of an insulating material.

The first top layer 65 of the partition 6 is formed of, for example, a metal material. In addition, the second top layer 66 of the partition 6 is formed of, for example, a conductive oxide. For the metal material forming the first top layer 65, for example, titanium, titanium nitride, molybdenum, tungsten, a molybdenum-tungsten alloy, or a molybdenum-niobium alloy can be used. For the conductive oxide forming the second top layer 66, for example, ITO or IZO can be used. Incidentally, the upper portion 62 may include three or more layers or may be composed of a single layer. Furthermore, the upper portion 62 may include a layer formed of an insulating material.

A common voltage is applied to the partition 6. This common voltage is applied to each of the upper electrodes UE1, UE2, and UE3 which are in contact with the lower portion 61. A pixel voltage is applied to the lower electrodes LE1, LE2, and LE3 through the pixel circuits 1 provided in the subpixels SP1, SP2, and SP3, respectively, based on the video signals of the signal lines S.

The organic layers OR1, OR2, and OR3 emit light based on the application of voltages. More specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light exhibiting the same color (for example, white). In this case, the display device DSP may comprise color filters which convert the light emitted from the light emitting layers into light exhibiting colors corresponding to the subpixels SP1, SP2, and SP3. In addition, the display device DSP may comprise a layer including a quantum dot which generates light exhibiting colors corresponding to the subpixels SP1, SP2, and SP3 by the excitation caused by the light emitted from the light emitting layers.

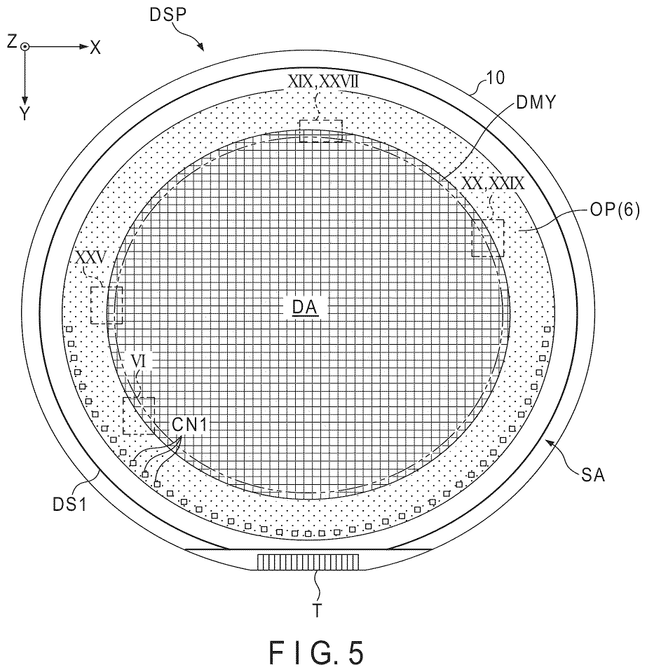

FIG. 5 is a schematic plan view showing the display device DSP. In the example of this figure, a dummy pixel area DMY and an outer circumferential area OP are provided in the surrounding area SA. The display area DA is surrounded by the dummy pixel area DMY. No images are displayed in the dummy pixel area DMY.

The outer circumferential area OP surrounds the dummy pixel area DMY. The partition 6 is also provided in the dummy pixel area DMY and the outer circumferential area OP. In the outer circumferential area OP, the partition 6 is covered with a sealing layer to be described later.

A dam structure DS1 is provided outside the sealing layer provided in the outer circumferential area OP. The terminal portion T is located outside the dam structure DS1. For example, each of the dummy pixel area DMY, the outer circumferential area OP, and the dam structure DS1 has a circular shape concentric with the display area DA.

In the outer circumferential area OP, the partition 6 is connected to a lower-layer power supply line, and the like, via a plurality of contact portions CN1. This power supply line is connected to the terminal portion T and receives a common voltage supply from the terminal portion T. The common voltage of the partition 6 is applied to the upper electrodes UE1, UE2, and UE3 which are in contact with the partition 6. In the example of FIG. 5, a plurality of contact portions CN1 are provided in an arc shape on the terminal portion T side.

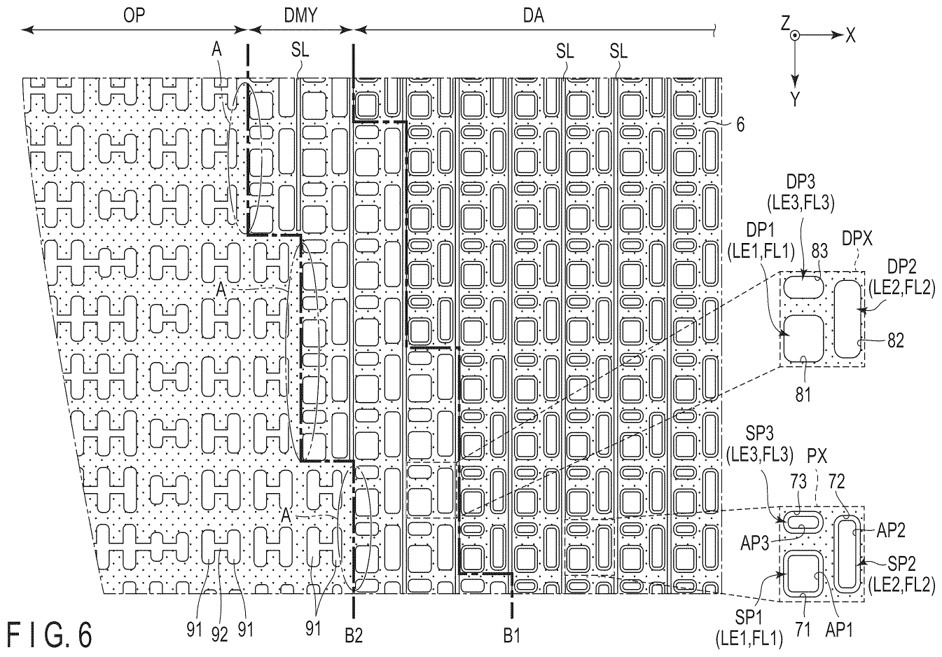

FIG. 6 is a schematic plan view showing an enlarged area surrounded by frame VI in FIG. 5. Several parts such as the sealing layer provided in the display area DA, the dummy pixel area DMY, and the outer circumferential area OP, and the like, are omitted in FIG. 6. The area surrounded by frame VI corresponds to, for example, a portion of the left side of a circular display device DSP.

In FIG. 6, a boundary between the display area DA and the dummy pixel area DMY, and a boundary between the dummy pixel area DMY and the outer circumferential area OP, are defined as boundaries B1 and B2, respectively, and are represented by dashed lines. The pixel PX in the display area DA is enlarged in FIG. 6.

A plurality of dummy pixels DPX are provided in the dummy pixel area DMY as shown in FIG. 6. For example, as enlarged and shown in FIG. 6, a dummy pixel DPX includes dummy subpixels DP1, DP2, and DP3. The dummy subpixels DP1, DP2, and DP3 have structures similar to those of the subpixels SP1, SP2, and SP3 as shown in FIG. 2, respectively.

The dummy subpixel DP1 includes the lower electrode LE1, the organic layer OR1, the upper electrode UE1, and the sealing layer SE11. In addition, the dummy subpixel DP2 includes the lower electrode LE2, the organic layer OR2, the upper electrode UE2, and the sealing layer SE12. In addition, the dummy subpixel DP3 includes the lower electrode LE3, the organic layer OR3, the upper electrode UE3, and the sealing layer SE13.

However, the dummy subpixels DP1, DP2, and DP3 are configured not to emit light. This configuration may be realized by, for example, disconnecting part of the pixel circuit 1 (shown in FIG. 1) in each of the dummy subpixels DP1, DP2, and DP3.

In addition, the pixel apertures AP1, AP2, and AP3 may be omitted in the dummy subpixels DP1, DP2, and DP3. As a result, the rib layer 5 is interposed between the organic layers OR1, OR2, and OR3 and the lower electrodes LE1, LE2, and LE3, and the voltage causing the organic layers OR1, OR2, and OR3 to emit light is not applied to the organic layers.

A part of the partition 6 is located in the dummy pixel area DMY and surrounds each of the plurality of dummy subpixels DPX. More specifically, the partition 6 surrounds each of the lower electrodes LE1, LE2, and LE3 of the dummy subpixels DP1, DP2, and DP3.

For example, the aperture pattern of the partition 6 in the display area DA and the dummy pixel area DMY is the same. In other words, the partition 6 includes apertures 71, 72, and 73 in the subpixels SP1, SP2, and SP3, respectively, and apertures 81, 82, and 83 in the dummy subpixels DP1, DP2, and DP3, respectively. The dummy subpixels DP1, DP2, and DP3 are provided in the areas including the apertures 81, 82, and 83, respectively.

The apertures 81, 82, and 83 have the same shapes as the apertures 71, 72, and 73, respectively. In addition, the arrangement of the apertures 81, 82, and 83 is the same as the arrangement of the apertures 71, 72, and 73.

The above-described slits SL are provided in the display area DA. The slits SL are also provided in the dummy pixel area DMY. In contrast, the slits SL are not provided in the outer circumferential area OP.

As described above, the partition 6 is also provided in the outer circumferential area OP. The partition 6 provided in the outer circumferential area OP is formed continuously with the partition 6 provided in the dummy pixel area DMY. The partition 6 includes a plurality of apertures 91 provided in the outer circumferential area OP.

The aperture pattern of the partition 6 in the outer circumferential area OP is different from, for example, the aperture pattern of the partition 6 in the display area DA and the dummy pixel area DMY. In addition, the shape of the apertures 91 is also different from that of the apertures 71, 72, and 73 and the apertures 81, 82, and 83.

The plurality of apertures 91 are arranged in the first direction X and the second direction Y. For example, the plurality of apertures 91 arranged in the first direction X may be connected via slits 92 extending in the first direction X. The shapes of the apertures 91 (the width in the first direction X and the width in the second direction Y) may be different from each other. Incidentally, the shape of the apertures 91 is not limited to the example shown in the figure, but may be the other shape.

In the present embodiment, the outer shape of each of the display area DA, the dummy pixel area DMY, and the outer circumferential area OP is a circular shape. Such an outer shape can be achieved by forming the boundary B1 between the display area DA and the dummy pixel area DMY, and the boundary B2 between the dummy pixel area DMY and the outer circumferential area OP in a stair-stepped shape as shown in FIG. 6. When the boundary B2 has a stair-stepped shape, the apertures 81, 82, and 83 of the dummy pixel area DMY and the aperture 91 of the outer circumferential area OP are arranged in the first direction X as surrounded by frame A.

In the present embodiment, no slits SL are provided at the part where the apertures 81, 82, and 83 and the aperture 91 are arranged in the first direction X. In other words, the partition 6 provided in the outer circumferential area OP is connected with, but is not separated from the partition 6 provided in the dummy pixel area DMY. A part of the left side of the display device DSP is shown in FIG. 6, but the right side of the display device DSP is similarly configured.

Incidentally, the lower electrodes LE1, LE2, and LE3 and the pixel circuits are provided in the display area DA and the dummy pixel area DMY, but are not provided in the outer circumferential area OP.

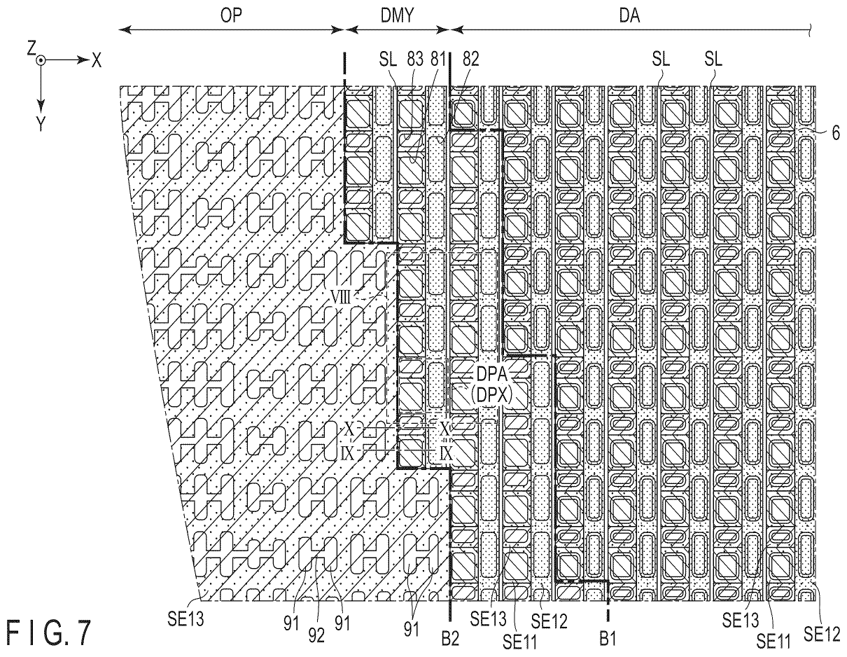

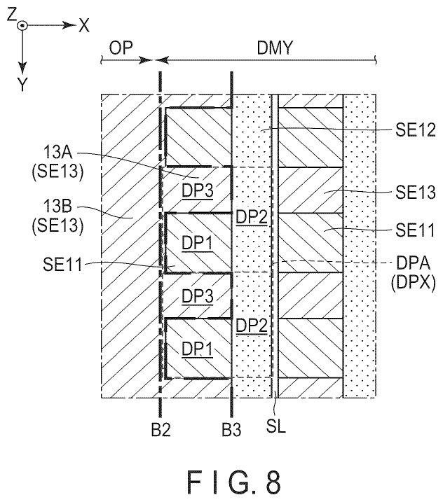

FIG. 7 is a schematic plan view showing a configuration of the sealing layers SE11, SE12, and SE13 provided in the display area DA, the dummy pixel area DMY, and the outer circumferential area OP. FIG. 8 is a schematic plan view showing an enlarged area surrounded by frame VIII in FIG. 7.

The area shown in FIG. 6 is shown in FIG. 7. The only sealing layers SE11, SE12, and SE13 are shown in FIG. 8. In FIG. 7 and following figures, the sealing layer SE11 may have a downward-sloping line pattern, the sealing layer SE12 have a dot-sloping pattern, and the sealing layer SE13 may have an upward-sloping line pattern.

Focus on the dummy pixel area DMY will be made. The sealing layer SE11 is provided in the dummy subpixels DP1, the sealing layer SE12 is provided in the dummy subpixels DP2, and the sealing layer SE13 is provided in the dummy subpixels DP3. The sealing layer SE12 is provided across, for example, the plurality of dummy subpixels DP2 arranged in the second direction Y.

In this case, a dummy pixel DPX provided at a position closest to the outer circumferential area OP, among the dummy pixels DPX, is referred to as a dummy pixel DPA. The dummy pixel DPA is located outermost in the dummy pixel are DMY.

Focus on a single dummy pixel DPA will be made here. As shown in FIG. 8, end portions of the sealing layers SE11, SE12, and SE13 are in contact with (closely attached to) each other, similarly to the sealing layers SE11, SE12, and SE13 provided in the display area DA.

In addition, focus on the dummy pixels DPA arranged in the second direction Y will be made here. The sealing layers SE11, SE12, and SE13 are arranged in the second direction Y and their end portions are in contact with each other. With respect to the slit SL, at least one of the sealing layers SE11, SE12, and SE13 may overlap with the slit SL.

Focus on the outer circumferential area OP will be made here. In the example of FIG. 7, the sealing layer SE13 is provided above the partition 6. In other words, each of the apertures 91 in the outer circumferential area OP overlaps with the sealing layer SE13.

The sealing layer SE13 provided in the outer circumferential area OP is connected to the sealing layer SE13 provided on the dummy subpixel DP3 of the dummy pixel DPA. In this case, the sealing layer SE13 provided on the dummy subpixel DP3 of the dummy pixel DPA is referred to as a sealing layer 13A, and the sealing layer SE13 provided in the outer circumferential area OP is referred to as a sealing layer 13B.

The sealing layer 13B is formed continuously with the sealing layer 13A, at a position above the partition 6 (partition 6C in FIG. 10) located between the dummy pixel area DMY and the outer circumferential area OP. In other words, the sealing layer 13B is connected to the sealing layer 13A. The sealing layer 13B can also be considered to be formed integrally with the sealing layer 13A. Focus on the boundary B2 will be made here. The sealing layer SE13 is formed to overlap with (straddle) the boundary B2.

The boundary between the sealing layer provided in the outer circumferential area OP and the sealing layer provided in the dummy pixel area DMY is defined as a boundary B3 (shown in FIG. 8). In FIG. 8, the boundary B3 is represented by a dashed line.

Focus on the left side of the display device DSP will be made here. The boundary B3 is formed between the sealing layers 13A and 13B, and the sealing layers SE11 and SE12 provided on the dummy pixel DPA. In such a case, the boundary B3 is formed in a zigzag pattern. Even when focus on a single dummy pixel DPA is made, the boundary B3 is formed in a zigzag pattern.

The sealing layer 13B is in contact with (closely attached to) the sealing layer SE11 provided on the dummy subpixel DP1 of the dummy pixel DPA. In addition, the sealing layer 13A is in contact with (closely attached to) each of the sealing layers SE11 and SE12 provided on the dummy subpixels DP1 and DP2 of the dummy pixel DPA. In other words, the sealing layers provided on the dummy pixel DPA and the outer circumferential area OP are in close contact with each other, and no gap is formed between their sealing layers.

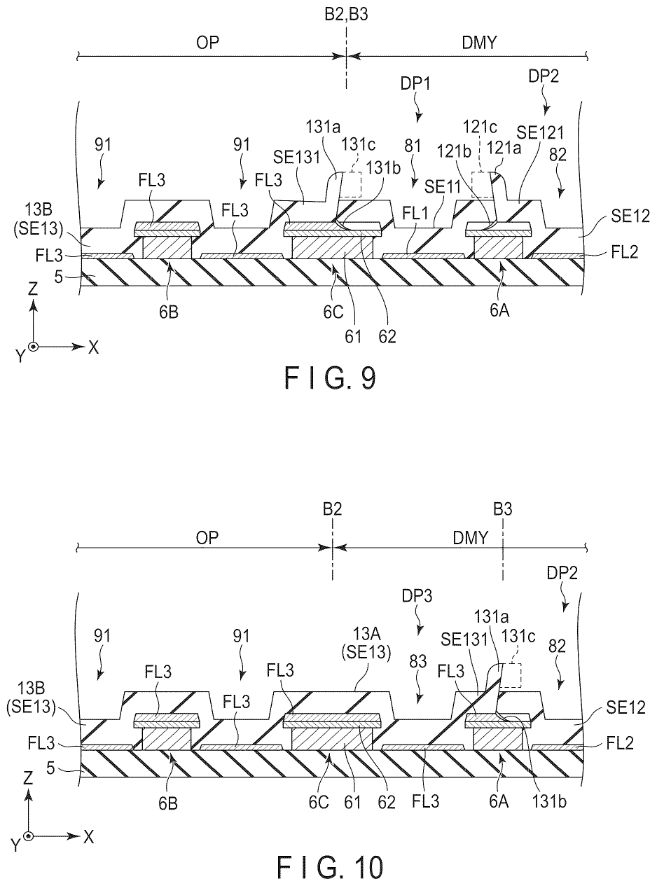

FIG. 9 is a schematic cross-sectional view showing the dummy pixel area DMY and the outer circumferential area OP along IX-IX line in FIG. 7. In this figure, the substrate 10, the circuit layer 11, the organic insulating layer 12, the sealing layer SE2, and the resin layers RS1 and RS2 are omitted.

In the following descriptions, the partition 6 provided in the dummy pixel area DMY is referred to as a partition 6A, the partition 6 provided in the outer circumferential area OP is referred to as a partition 6B, and the partition 6 provided at the boundary B2 between the dummy pixel area DMY and the outer circumferential area OP is referred to as a partition 6C. In addition, although not shown, the lower portion 61 includes a bottom layer 63 and a stem layer 64 (shown in FIG. 3), while the upper portion 62 includes a first top layer 65 and a second top layer 66 (shown in FIG. 3).

The lower electrode LE1 (not shown), the stacked film FL1, and the sealing layer SE11 are provided in the dummy subpixel DP1. The sealing layer SE11 is provided above the stacked film FL1. The lower electrode LE2 (not shown), the stacked film FL2, and the sealing layer SE12 are provided in the dummy subpixel DP2. The sealing layer SE12 is provided above the stacked film FL2.

In the example of FIG. 9, no pixel apertures are provided in the rib layer 5, in the dummy subpixels DP1 and DP2. The sealing layer SE12 continuously covers the stacked film FL2 and a part of the partition 6A. The sealing layer SE11 continuously covers the stacked film FL1 and parts of the partitions 6A and 6C. The sealing layer SE13 continuously covers the stacked films FL3 and parts of the partitions 6B and 6C.

Focus on the sealing layer SE12 will be made here. The sealing layer SE12 includes an overlapping portion SE121 located above the partition 6A between the dummy subpixels DP1 and DP2. The overlapping portion SE121 is in contact with the end portion of the sealing layer SE11. In other words, the overlapping portion SE121 is not separated from the end portion of the sealing layer SE11. The overlapping portion SE121 may include a protruding portion 121a that protrudes upwardly. The protruding portion 121a is provided at a position higher than the sealing layer SE11, above the partition 6A.

In addition, the overlapping portion SE121 may further include an extending portion 121b extending toward a gap formed between the sealing layer SE11 and the upper portion 62 of the partition 6A. This gap occurs due to loss of the stacked film FL1 during the manufacturing process.

The protruding portion 121a of the sealing layer SE12 may overlap with the sealing layer SE11. More specifically, the protruding portion 121a may include a portion 121c (represented by a dashed line in FIG. 9) which overlaps with the sealing layer SE11. In this case, the partition 6A, the sealing layer SE11, and the protruding portion 121a of the sealing layer SE12 are arranged in this order, in the third direction Z. The portion 121c may or may not be in contact with the sealing layer SE11.

Focus on the sealing layer SE13 will be made here. The sealing layer SE13 includes an overlapping portion SE131 located above the partition 6C between the dummy subpixel DP1 and the outer circumferential area OP. The overlapping portion SE131 is in contact with the end portion of the sealing layer SE11. The overlapping portion SE131 may include a protruding portion 131a that protrudes upwardly. The protruding portion 131a is provided at a position higher than the sealing layer SE11, above the partition 6C.

In addition, the overlapping portion SE131 may further include an extending portion 131b extending toward a gap formed between the sealing layer SE11 and the upper portion 62 of the partition 6C. This gap occurs due to loss of the stacked film FL1 during the manufacturing process. The stacked film FL3 is provided between the partition 6C and the overlapping portion SE131. The stacked film FL3 is surrounded by the partition 6C, the overlapping portion SE131, and the protruding portion 131b.

The protruding portion 131a of the sealing layer SE13 may overlap with the sealing layer SE11. More specifically, the protruding portion 131a may include a protruding portion 131c (represented by a dashed line in FIG. 9) which overlaps with the sealing layer SE11. In this case, the partition 6C, the sealing layer SE11, and the protruding portion 131a of the sealing layer SE13 are arranged in this order, in the third direction Z. The portion 131c may or may not be in contact with the sealing layer SE11.

FIG. 10 is a schematic cross-sectional view showing the dummy pixel area DMY and the outer circumferential area OP along X-X line in FIG. 7. In this figure, the substrate 10, the circuit layer 11, the organic insulating layer 12, the sealing layer SE2, and the resin layers RS1 and RS2 are omitted.

Although not shown, the lower portion 61 includes a bottom layer 63 and a stem layer 64 (shown in FIG. 3), while the upper portion 62 includes a first top layer 65 and a second top layer 66 (shown in FIG. 3). The lower electrode LE3 (not shown), the stacked films FL3, and the sealing layer SE13A are provided in the dummy subpixel DP3. The sealing layer 13A is provided above the stacked films FL3.

In the example of FIG. 10, no pixel apertures are provided in the rib layer 5, in the dummy subpixel DP3. The stacked films FL3 are provided on the partition 6B, the upper portion 62 of the partition 6C between the dummy subpixel DP3 and the peripheral region OP, and the apertures 83 and 91. In the outer circumferential area OP, the sealing layer 13B is provided above the stacked films FL3.

In other words, the sealing layer SE13 (sealing layer 13A and sealing layer 13B) continuously covers these stacked films FL3, the partition 6B, and the partition 6C. The sealing layer 13A is connected to the sealing layer 13B above the partition 6C.

Focus on the sealing layer SE13 will be made here. The overlapping portion SE131 is located above the partition 6A between the dummy subpixels DP2 and DP3. The overlapping portion SE131 is in contact with an end portion of the sealing layer SE12. The overlapping portion SE131 may include a protruding portion 131a that protrudes upwardly. The protruding portion 131a is provided at a position higher than the sealing layer SE12, above the partition 6A.

In addition, in the example of FIG. 10, the overlapping portion SE131 may further include an extending portion 131b extending toward a gap formed between the sealing layer SE12 and the upper portion 62 of the partition 6A. The stacked film FL3 is provided between the partition 6A and the overlapping portion SE131.

In addition, the protruding portion 131a of the sealing layer SE13 may overlap with the sealing layer SE11. More specifically, the protruding portion 131a may include a protruding portion 131c (represented by a dashed line in FIG. 10) which overlaps with the sealing layer SE11. In this case, the partition 6A, the sealing layer SE12, and the protruding portion 131a of the sealing layer SE13 are arranged in this order, in the third direction Z. The portion 131c may or may not be in contact with the sealing layer SE12.

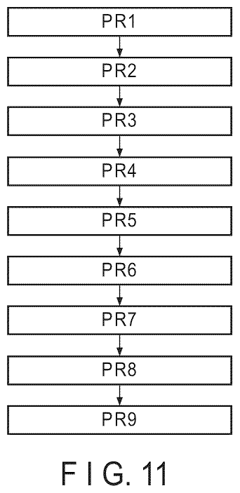

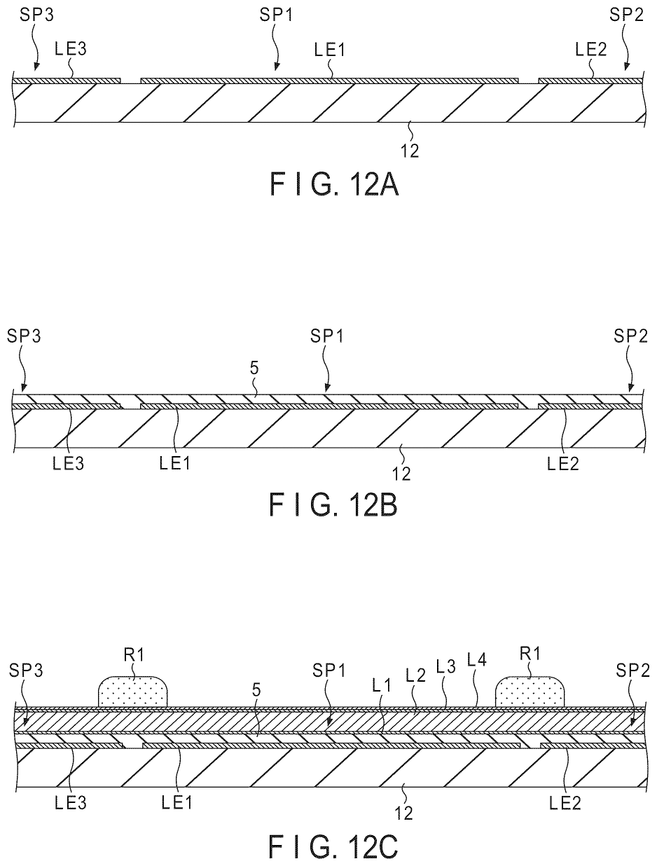

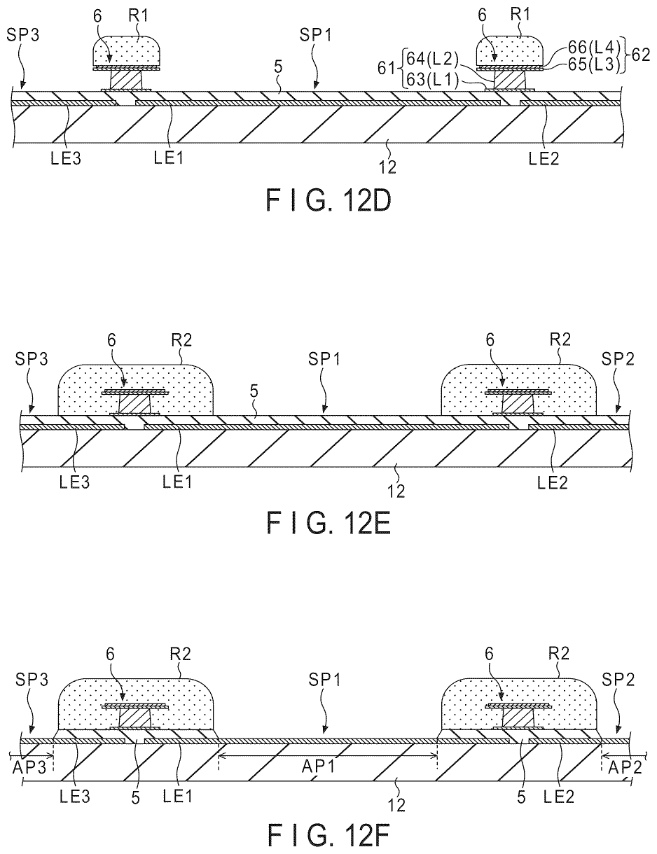

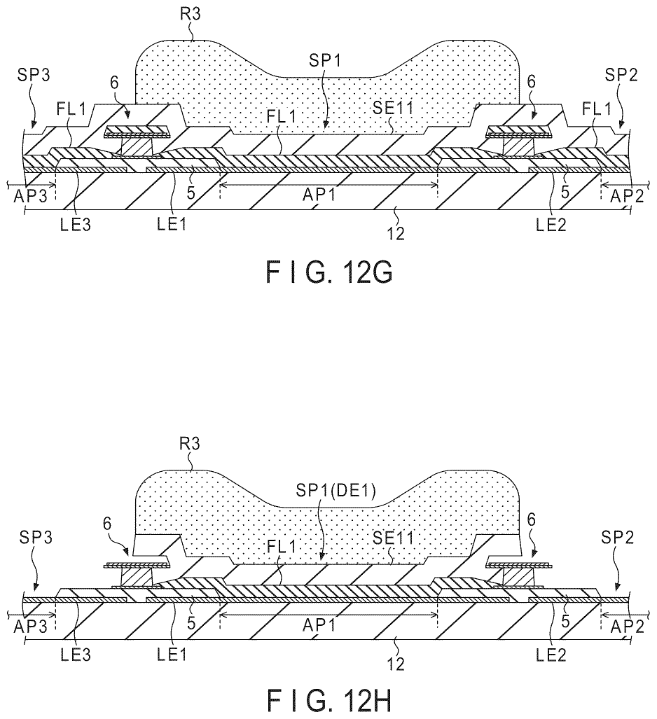

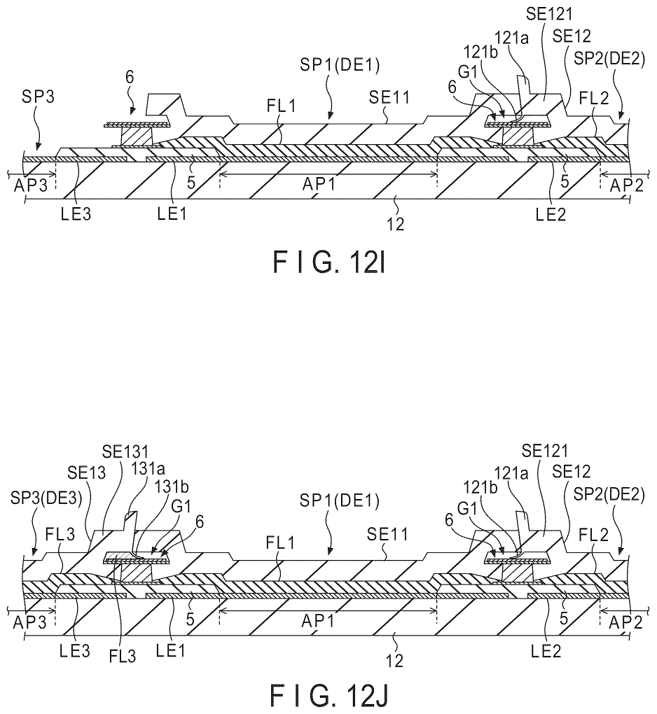

Next, an example of a method of manufacturing the display device DSP will be described. FIG. 11 is a flowchart showing an example of a method of manufacturing the display device DSP. FIG. 12A to FIG. 12J are schematic cross-sectional views showing processes of manufacturing the display device DSP. In FIG. 12A to FIG. 12J, focus on the display area DA is mainly made and the elements located under the organic insulating layer 12 are omitted.

To form the display device DSP, first, the circuit layer 11 and the organic insulating layer 12 are formed on the substrate 10 (process PR1 in FIG. 11). Subsequently, as shown in FIG. 12A, the lower electrodes LE1, LE2, and LE3 are formed on the organic insulating layer 12 (process PR2 in FIG. 11).

Subsequently, as shown in FIG. 12B, the rib layer 5 which covers the lower electrodes LE1, LE2, and LE3 is formed (process PR3 in FIG. 11). At this time, the pixel aperture AP1, AP2 or AP3 is not provided in the rib layer 5. The rib layer 5 can be formed by chemical vapor deposition (CVD).

After the formation of the rib layer 5, a process for forming the partition 6 is performed (process PR4 in FIG. 11). In the process PR4, as shown in FIG. 12C, a first layer L1 which is processed so as to be the bottom layer 63, a second layer L2 which is processed so as to be the stem layer 64, a third layer L3 which is processed so as to be the first top layer 65, and a fourth layer L4 which is processed so as to be the second top layer 66 are formed in order. Furthermore, a resist R1 is provided on the fourth layer L4. The resist R1 has been patterned into the shape of the partition 6. The first layer L1, the second layer L2, the third layer L3, and the fourth layer L4 can be formed by, for example, sputtering.

After that, the first layer L1, the second layer L2, the third layer L3, and the fourth layer L4 are patterned using the resist R1 as a mask. In one example, the first layer L1 is formed of titanium nitride, the second layer L2 is formed of aluminum, the third layer L3 is formed of titanium, and the fourth layer L4 is formed of ITO. In this case, the above patterning may include wet etching for removing the portion of the fourth layer L4 exposed from the resist R1, dry etching for removing the portions of the first, second and third layers L1, L2, and L3 exposed from the resist R1, and wet etching for reducing the width of the second layer L2.

As shown in FIG. 12D, the partition 6 is formed in the display area DA through the process PR4. After the formation of the partition 6, the resist R1 is removed (peeled off). In the above-described wet etching for reducing the width of the second layer L2, the second top layer 66 (fourth layer L4) may also be slightly corroded. When this corrosion occurs, the width of the second top layer 66 becomes smaller than that of the first top layer 65.

Subsequently, a process for providing the pixel apertures AP1, AP2, and AP3 is performed (process PR5 in FIG. 11). In this process PR5, as shown in FIG. 12E, a resist R2 which covers the partition 6 is formed. Furthermore, dry etching for the rib layer 5 is performed using the resist R2 as a mask. As a result, as shown in FIG. 12F, the pixel apertures AP1, AP2, and AP3 from which the lower electrodes LE1, LE2, and LE3 are exposed are formed in the rib layer 5. After the above-described dry etching, the resist R2 is removed (peeled off).

After the process PR5, a process for forming the display element DE1 is performed (process PR6 in FIG. 11). To form the display element DE1, first, as shown in FIG. 12G, the stacked film FL1 and the sealing layer SE11 are formed. As shown in FIG. 3, the stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1. The organic layer OR1, the upper electrode UE1, and the cap layer CP1 can be formed by, for example, vapor deposition. In addition, the sealing layer SE11 can be formed by, for example, CVD.

The stacked film FL1 and the sealing layer SE11 are formed not only in the display area DA but also in the surrounding area SA (dummy pixel area DMY and outer circumferential area OP). The stacked film FL1 is divided into a plurality of parts by the partition 6 having an overhang shape. The sealing layer SE11 continuously covers the parts into which the stacked film FL1 is divided, and the partition 6.

Next, the stacked film FL1 and the sealing layer SE11 are patterned. In this patterning, as shown in FIG. 12G, a resist R3 is provided on the sealing layer SE11. The resist R3 covers the subpixel SP1 and part of the partition 6 around the subpixel SP1.

After that, an etching process using the resist R3 as a mask is performed. As a result, as shown in FIG. 12H, the parts of the stacked film FL1 and the sealing layer SE11, which are exposed from the resist R3, are removed.

In other words, the portions of the stacked film FL1 and the sealing layer SE11, which overlap with the lower electrode LE1, remain, and the other portions are removed. The display element DE1 is thereby formed in the subpixel SP1.

In addition, focus on the dummy pixel area DMY will be made. The stacked film FL1 and the sealing layer SE11 provided on the dummy subpixel DP1 remain. Incidentally, the stacked film FL1 and sealing layer SE11 are removed by this etching process, in the outer circumferential area OP.

This etching process includes wet etching and dry etching which are performed in order for the sealing layer SE11, the cap layer CP1, the upper electrode UE1, and the organic layer OR1. After these etching processes, the resist R3 is removed (peeled off).

Incidentally, the stacked film FL1 located under the sealing layer SE11 on the partition 6 is also removed in wet etching for the stacked film FL1. As a result, a gap is formed between the sealing layer SE11 located above the partition 6 and the partition 6. Since the stacked film FL1 which constitutes the display element DE1 is completely surrounded by the sealing layer SE11 and the partition 6, this stacked film FL1 is not corroded by the above-described wet etching.

Prior to the above-described wet etching, the stacked film FL1 is also formed in the gap between the partition 6 and the sealing layer SE11. The stacked film FL1 in this gap is removed as the etchant penetrates from the vicinity of the end portion of the sealing layer SE11 to the lower side of the sealing layer SE11 in the wet etching.

After the process PR6, a process for forming the display element DE2 is performed (process PR7 in FIG. 11). The display element DE2 can be formed in the same procedure as that of the display element DE1. In other words, to form the display element DE2, the stacked film FL2 and the sealing layer SE12 are entirely formed over the display area DA and surrounding area SA (dummy pixel area DMY and outer circumferential area OP). As shown in FIG. 3, the stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2.

The organic layer OR2, the upper electrode UE2, and the cap layer CP2 can be formed by, for example, vapor deposition. In addition, the sealing layer SE12 can be formed by, for example, CVD. The stacked film FL2 is divided into a plurality of parts by the partition 6 having an overhang shape. The sealing layer SE12 continuously covers the parts into which the stacked film FL2 is divided, and the partition 6. By patterning the stacked film FL2 and the sealing layer SE2, the display element DE2 is formed in the subpixel SP2 as shown in FIG. 12I.

The end portions of the sealing layers SE11 and SE12 located above the partition 6 between the subpixels SP1 and SP2 are in contact with each other. When the sealing layer SE12 is formed to be in contact with the sealing layer SE11, a protruding portion 121a may be formed in the overlapping portion SE121, in the sealing layer SE12 which is formed in a process followed by the formation of the sealing layer SE11. Furthermore, an extending portion 121b extending toward the gap G1 formed between the sealing layer SE11 and the upper portion 62 of the partition 6 may be formed in the sealing layer SE12.

Incidentally, the stacked film FL2 is also formed in the gap between the partition 6 and the sealing layer SE12. The stacked film FL2 in this gap is removed as the etchant penetrates from the vicinity of the end portion of the sealing layer SE12 to the lower side of the sealing layer SE12 in the wet etching.

In addition, focus on the dummy pixel area DMY will be made. The stacked film FL2 and the sealing layer SE12 provided on the dummy subpixel DP2 remain. When the sealing layer SE12 is formed to be in contact with the sealing layer SE11, a protruding portion 121a may be formed in the overlapping portion SE121, in the sealing layer SE12 which is formed in a process followed by the formation of the sealing layer SE11.

Furthermore, an extending portion 121b extending toward the gap formed between the sealing layer SE11 and the upper portion 62 of the partition 6 may be formed in the sealing layer SE12. Incidentally, the stacked film FL2 and sealing layer SE12 are removed by this etching process, in the outer circumferential area OP.

After the process PR7, a process for forming the display element DE3 is performed (process PR8 in FIG. 11). The display element DE3 can be formed in the same procedure as the procedures of the display elements DE1 and DE2.

In other words, to form the display element DE3, the stacked film FL3 and the sealing layer SE13 are entirely formed over the display area DA and surrounding area SA (dummy pixel area DMY and outer circumferential area OP). As shown in FIG. 3, the stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3.

The organic layer OR3, the upper electrode UE3 and the cap layer CP3 can be formed by, for example, vapor deposition. In addition, the sealing layer SE13 can be formed by, for example, CVD. The stacked film FL3 is divided into a plurality of parts by the partition 6 having an overhang shape. The sealing layer SE13 continuously covers the parts into which the stacked film FL3 is divided, and the partition 6. By patterning the stacked film FL3 and the sealing layer SE13, the display element DE3 is formed in the subpixel SP3 as shown in FIG. 12J.

The end portions of the sealing layers SE11 and SE13 located above the partition 6 between the subpixels SP1 and SP3 are in contact with each other. When the sealing layer SE13 is formed to be in contact with the sealing layer SE11, a protruding portion 131a may be formed in the overlapping portion SE131, in the sealing layer SE13 formed in the process following the sealing layer SE11. Furthermore, an extending portion 131b that extends toward the gap G1 formed between the sealing layer SE11 and the upper portion 62 of the partition 6 may be formed in the sealing layer SE13.

As shown in FIG. 12J, a stacked film FL3 is formed in the gap between the partition 6 and the sealing layer SE13. Since the end portions of the sealing layer SE11 and the sealing layer SE13 are in contact with each other, impregnation of the etchant from the vicinity of the end portion of the sealing layer SE13 toward the lower side of the sealing layer SE13 during the wet etching is suppressed. As a result, the stacked film FL3 remains in this gap.

Furthermore, this stacked film FL3 is surrounded not only by the partition 6 and the overlapping portion SE131, but also by the extending portion 131b. Consequently, impregnation of the etchant into the gap from the upper side is further suppressed.

Incidentally, when the sealing layer SE13 is formed to be in contact with the sealing layer SE12 even above the partition 6 between the subpixels SP2 and SP3, the protruding portion 131a, and the extending portion 131b extending toward the gap formed between the sealing layer SE11 and the upper portion 62 of the partition 6 may be formed at the overlapping portion SE131, in the sealing layer SE13 formed in the process following the formation of the sealing layer SE12.

In addition, focus on the dummy pixel area DMY and the outer will be made. The stacked film FL3 and the sealing layer SE13 provided in the dummy subpixel DP3 and the outer circumferential area OP remain. The sealing layers SE11, SE12, and SE13 shown in FIG. 7 are formed in the dummy pixel area DMY and the outer circumferential area OP through the processes PR6 to PR8 in FIG. 11.

When the sealing layer SE13 is formed in the dummy pixel area DMY and the outer circumferential area OP so as to be in contact with the sealing layers SE11 and SE12, the protruding portion 131a and the extending portion 131b may be formed in the overlapping portion SE131, in the sealing layer SE13, which is formed in a process following the sealing layers SE11 and SE12, as shown in FIG. 9 and FIG. 10.

In addition, in the examples shown in FIG. 12I and FIG. 12J, the portion 121c of the sealing layer SE12, which overlaps with the sealing layer SE11, and the portion 131c of the sealing layer SE13, which overlaps with the sealing layer SE11, as shown in FIG. 4, are removed. However, patterning may be performed such that the portions 121c and 131c remain. In addition, the sealing layers SE12 and SE13 provided in the dummy pixel area DMY and the outer circumferential area OP may also be patterned to leave the portions 121c and 131c as represented by dashed lines in FIG. 9 and FIG. 10.

After the process PR8, the resin layer RS1, the sealing layer SE2, and the resin layer RS2 are formed in order (process PR9 in FIG. 11). To form the resin layers RS1 and RS2, for example, an ink-jet method can be used. To form the sealing layer SE2, for example, CVD can be used.

In the present embodiment, it is assumed that the display elements DE1, DE2, and DE3 are formed in this order. In this case, the display element DE1 corresponds to the display element of the first color, the display element DE2 corresponds to the display element of the second color, and the display element DE3 corresponds to the display element of the third color. Incidentally, the display elements DE1, DE2, and DE3 may be formed in a different order.

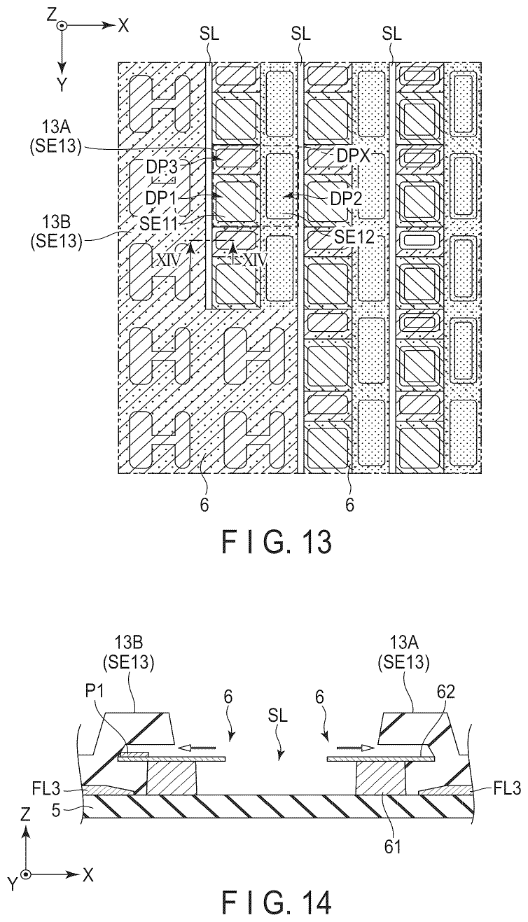

FIG. 13 is a schematic plan view showing a display device according to a comparative example of the present embodiment. FIG. 14 is a schematic cross-sectional view showing the display device along XIV-XIV line in FIG. 13.

In the display device DSP according to the comparative example, as shown in FIG. 13, slits SL are further provided between the dummy pixel area DMY and the outer circumferential area OP. In other words, the partition 6 provided in the outer circumferential area OP is separated from the partition 6 provided in the dummy pixel area DMY.

Focus on the sealing layers 13A and 13B will be made here. As shown in FIG. 13, the sealing layer 13B is separated from the sealing layer 13A. In other words, an end portion of the sealing layer 13B is not in contact with an end portion of the sealing layer 13A. Although not shown, the sealing layer 13B is not in contact with the sealing layer SE11 provided on the dummy subpixel DP1 of the dummy pixel DPA either.

As shown in FIG. 14, a gap formed between end portions of the sealing layer SE13 and upper portions 62 of the partition 6A opens toward the slit SL. Similarly, a gap formed between end portions of the sealing layer SE13 and upper portions 62 of the partition 6B opens toward the slit SL.

In such a case, during the process PR8 in FIG. 11, the stacked film FL3 provided in the gap may be lost by the etchant impregnating from the slit SL and the upper side toward the gap as indicated by the arrow. However, the degree of loss of the stacked film FL3 may vary depending on the position of the boundary B2. As shown in the example of FIG. 14, the stacked film FL3 may remain above the partition 6 provided in the outer circumferential area OP. In FIG. 14, the remaining stacked film FL3 is shown as a residual portion P1.

Such variation in the degree of loss of the stacked film FL3 above the partition 6 may cause degradation in the appearance of the outer circumferential area OP. For example, rainbow-like patterns (discoloration) may appear near the boundary B2 and the appearance of the outer circumferential area OP may be degraded, by the residual portion P1.

When such a pattern occurs, alignment marks formed in the outer circumferential area OP become difficult to see when a cover glass is provided above the resin layer RS2 in the processes following the process PR9 in FIG. 11. Such degradation may cause a decrease in the yield of the display device DSP.

In the display device DSP according to the present embodiment, the partition 6 provided in the outer circumferential area OP is formed continuously with the partition 6 provided in the dummy pixel area DMY. In other words, no slit SL is provided between the dummy pixel area DMY and the outer circumferential area OP. The impregnation of the etchant through the slit SL can be thereby suppressed.

Furthermore, end portions of the sealing layer provided in the dummy pixel area DMY and the sealing layer provided in the outer circumferential area OP at the boundary B3 (shown in FIG. 8), are in contact with each other above the partition 6. Impregnation of the etchant from the upper side can be suppressed by the end portions of the sealing layers in contact with each other above the partition 6.

As described above, impregnation of the etchant which makes the stacked film FL3 provided above the partition 6C lost can be suppressed and the stacked film FL3 can be left above partition 6C, by providing the partition 6 and bringing the end portions of the sealing layers into contact with each other above the partition 6.

In other words, variation in the degree of loss of the stacked film FL3 above the partition 6 can be suppressed depending on the position of the boundary B2. For example, the rainbow-like pattern is less likely to occur and the appearance of the outer circumferential area OP can be improved, by leaving the entire stacked film FL3 above the partition 6C.

An inconvenience that alignment marks become difficult to see can be thereby eliminated. Consequently, the yield of the display device DSP can be improved in the present embodiment.

Furthermore, in the present embodiment, the sealing layer SE13 includes an extending portion 131b. More specifically, when the sealing layer SE13 is formed to be in contact with the sealing layers SE11 and SE12, the extending portion 131b may be formed continuously along the boundary B3, in the sealing layer SE13.

As shown in FIG. 9 and FIG. 10, the stacked film FL3 provided above the partition 6C is also surrounded by the protruding portion 131b. In other words, the protruding portion 131b functions as a wall which suppresses the impregnation of the etchant into the stacked film FL3. Since it is more difficult for the etchant to reach the stacked film FL3 from the upper side by the extending portion 131b, undesired loss of the stacked film FL3 can be further suppressed. As a result, the appearance of the peripheral region OP in the display device DSP can be improved.

In the present embodiment, the organic layer OR3 is an example of a first organic layer and a second organic layer, the stacked film FL3 is an example of a first stacked film and a second stacked film, the organic layer OR1 is an example of a third organic layer, the stacked film FL1 is an example of a third stacked film, the dummy subpixel DP3 of the dummy pixel DPA is an example of a first dummy subpixel, the dummy subpixel DP1 of the dummy pixel DPA is an example of a second dummy subpixel, the sealing layer 13A is an example of a first sealing layer, the sealing layer 13B is an example of a second sealing layer, and the sealing layer SE11 is an example of a third sealing layer. The organic layer OR3 of the stacked film FL3 provided in the outer circumferential area OP includes the same light emitting layer as the organic layer OR3 of the stacked film FL3 arranged in the dummy subpixel DP3.

Next, other embodiments will be described. Incidentally, in the other embodiments described below, the same components as those of the above-described first embodiment may be denoted by the same reference numerals as those in the first embodiment, and their detailed description may be omitted or simplified.

### Second Embodiment

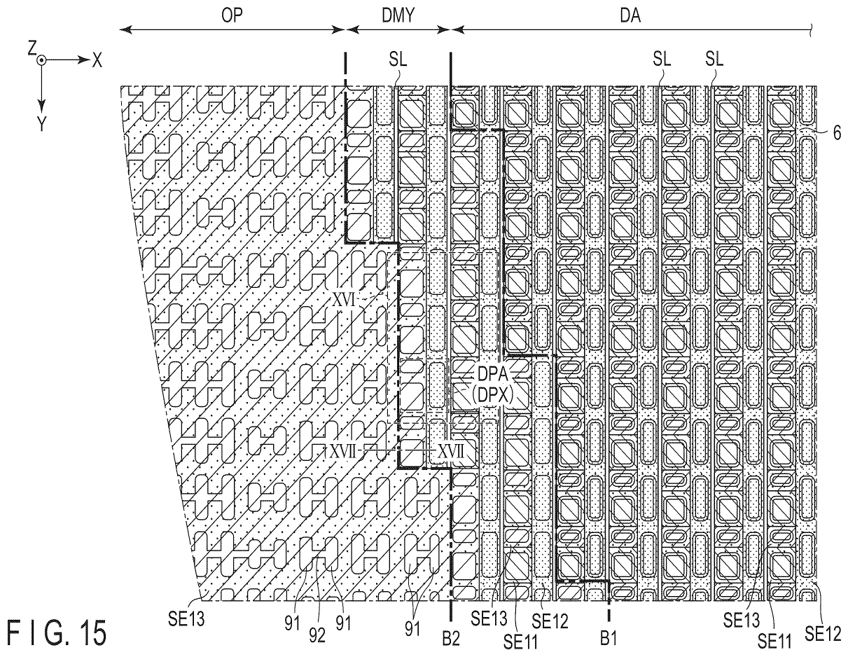

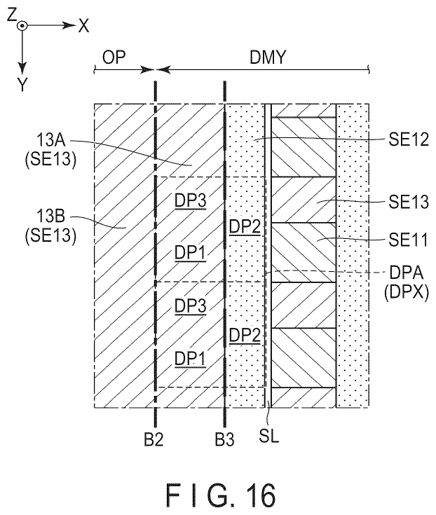

FIG. 15 is a schematic plan view showing a display device DSP according to the present embodiment. FIG. 16 is a schematic enlarged view showing a XVI portion in FIG. 15. In FIG. 16, focus on sealing layers SE11, SE12, and SE13 is mainly made and the other elements are omitted. In the present embodiment, a configuration in a dummy pixel area DMY is different from that in the first embodiment.

As shown in FIG. 15 and FIG. 16, the sealing layer 13A is provided across the dummy subpixels DP1 and DP3 of the dummy pixel DPA. Focus on a plurality of dummy pixels DPA will be made here. The sealing layer 13A is provided across the dummy subpixels DP1 and DP3 of a plurality of dummy pixels DPA aligned in the second direction Y. In other words, the sealing layer 13A is provided on the dummy subpixels DP1 and DP3 of at least two adjacent dummy pixels DPA.

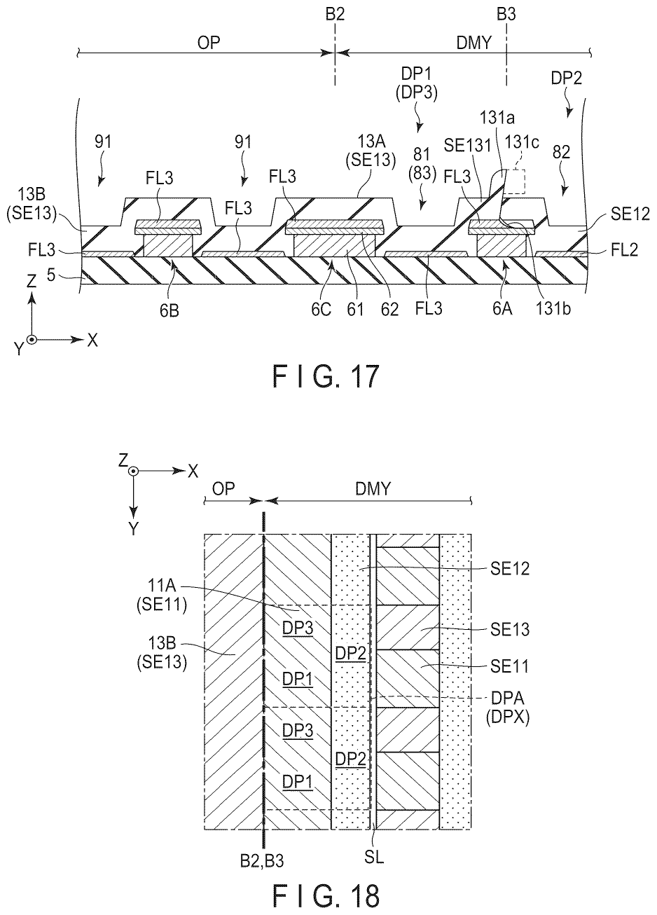

The sealing layer 13B is formed continuously with the sealing layer 13A, at a position above the partition 6 (partition 6C in FIG. 17) located between the dummy pixel area DMY and the outer circumferential area OP. In other words, the sealing layer 13B is connected to the sealing layer 13A. Focus on the boundary B2 will be made here. The sealing layer SE13 is formed to overlap with (straddle) the boundary B2.

Focus on the left side of the display device DSP will be made here. The boundary B3 is formed between the sealing layer 13A and the sealing layer SE12 provided on the dummy pixel DPA. In such a case, the boundary B3 is formed in a straight line.

In addition, the sealing layer 13A is in contact with the sealing layer SE12 provided on the dummy subpixel DP2 of the dummy pixel DPA. In other words, the sealing layers provided on the dummy pixel DPA and the outer circumferential area OP are in close contact with each other, and no gap is formed between the sealing layers.

FIG. 17 is a schematic cross-sectional view showing the dummy pixel area DMY and the outer circumferential area OP along XVII-XVII line in FIG. 15. In this figure, the substrate 10, the circuit layer 11, the organic insulating layer 12, the sealing layer SE2, and the resin layers RS1 and RS2 are omitted.

In the present embodiment, stacked films FL3 and the sealing layer 13A are provided on the dummy subpixel DP1. The sealing layer SE13 is provided above the stacked films FL3. Although not shown, the stacked films FL3 and the sealing layer 13A are also provided on a dummy subpixel DP3.

The stacked films FL3 are provided on the partition 6B, the upper portion 62 of the partition 6C between the dummy subpixels DP1 and DP3 and the peripheral region OP, and the apertures 81, 83, and 91. The sealing layer SE13 (sealing layer 13A and sealing layer 13B) continuously covers these stacked films FL3, the partition 6B, and the partition 6C. In other words, the sealing layer 13A is connected to the sealing layer 13B above the partition 6C.

End portions of the sealing layers SE12 and SE13 are in contact with each other, on the partition 6A between the dummy subpixels DP1 and DP2. The sealing layer SE13 includes an overlapping portion SE131 located above the partition 6A. The overlapping portion SE131 is in contact with an end portion of the sealing layer SE12. The overlapping portion SE131 may include a protruding portion 131a that protrudes upwardly. The protruding portion 131a is provided at a position higher than the sealing layer SE12, above the partition 6A.

In addition, the overlapping portion SE131 may further include an extending portion 131b extending toward a gap formed between the sealing layer SE12 and the upper portion 62 of the partition 6A. For example, the extending portion 131b is formed along the second direction Y. The stacked film FL3 is provided between the partition 6A and the overlapping portion SE131.

In addition, the protruding portion 131a may include a protruding portion 131c (represented by a dashed line in FIG. 17) which overlaps with the sealing layer SE12. In this case, the partition 6A, the sealing layer SE12, and the protruding portion 131a of the sealing layer SE13 are arranged in this order, in the third direction Z. Incidentally, the elements above the partition 6A between the dummy subpixels DP2 and DP3 are configured similarly to FIG. 17.

The same advantages as those of the first embodiment can also be obtained in the present embodiment. In the present embodiment, an extending portion 131b (shown in FIG. 17) can be formed linearly along the second direction Y. By forming the protruding portion 131b linearly, the impregnation of the etchant from the upper side can be further suppressed as compared to the first embodiment.

Furthermore, during the process PR8 in FIG. 11, when applying resist for processing the stacked films FL3 and sealing layer SE13, bubbles may be formed at the bent portion of the boundary B3. If a process for forming the display element DE3 is performed in a state where bubbles are formed at the position, the bubbles may burst at the time of the reduced-pressure drying of the resist for patterning the stacked film FL3 and the sealing layer SE13, and the area which needs to be covered with the resist may be exposed.

By forming the boundary B3 in a straight line similarly to the present embodiment, the number of bent portions of the boundary B3 can be reduced as compared to the first embodiment. Formation of bubbles during applying the resist can be thereby suppressed. The yield of the display device DSP can be further improved in the present embodiment.

In the present embodiment, the organic layer OR3 is an example of a first organic layer and a second organic layer, the stacked film FL3 is an example of a first stacked film and a second stacked film, the dummy subpixel DP3 of the dummy pixel DPA is an example of a first dummy subpixel, the dummy subpixel DP1 of the dummy pixel DPA is an example of a second dummy subpixel, the sealing layer 13A is an example of a first sealing layer, and the sealing layer 13B is an example of a second sealing layer.

### Third Embodiment

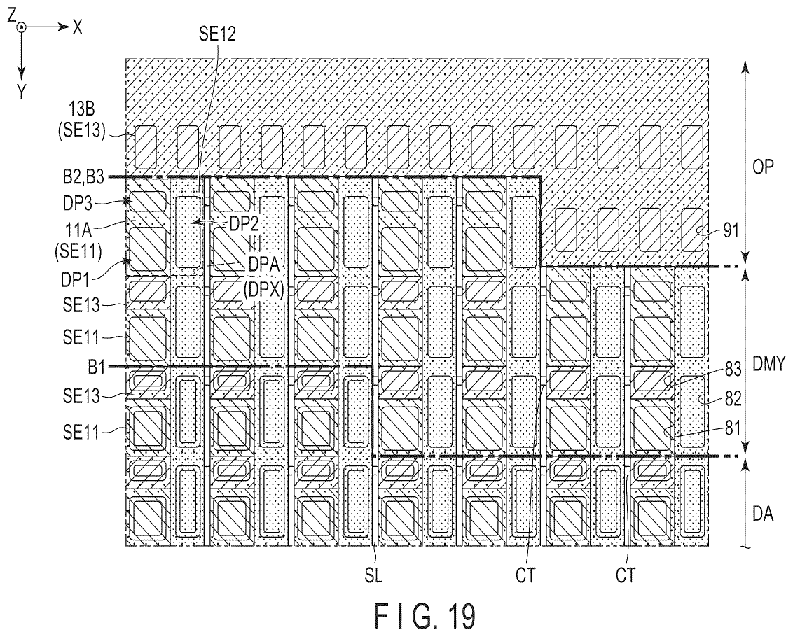

FIG. 18 is a schematic plan view showing a display device DSP according to the present embodiment. In FIG. 18, focus on sealing layers SE11, SE12, and SE13 is mainly made and the other elements are omitted. In the present embodiment, a configuration of dummy subpixels DP1 and DP3 of a dummy pixel DPA is different from that in the second embodiment.

In the present embodiment, a stacked film FL1 and the sealing layer SE11 are provided on the dummy subpixels DP1 and DP3. In other words, the sealing layer SE11 is provided across the dummy subpixels DP1 and DP3. The sealing layer SE11 is provided above the stacked film FL1. The sealing layer SE11 provided on the dummy pixel DPA is shown as a sealing layer 11A.

In the example shown in FIG. 18, the sealing layer 11A is provided across the dummy subpixels DP1 and DP3 of a plurality of dummy pixels DPA arranged in the second direction Y. In other words, the sealing layer 11A is provided on the dummy subpixels DP1 and DP3 of at least two adjacent dummy pixels DPA.

Focus on the left side of the display device DSP will be made here. The boundary B3 is formed between the sealing layer 13B and the sealing layer 11A provided on the dummy pixel DPA. In the example of FIG. 18, the boundary B3 overlaps with the boundary B2. The sealing layer 13B is in contact with the sealing layer 11A provided on the dummy subpixels DP1 and DP3 of the dummy pixel DPA.

The cross-section including the boundary B2 between the dummy pixel area DMY and the outer circumferential area OP in the present embodiment is configured similarly to, for example, FIG. 9 in the first embodiment. More specifically, the sealing layer SE11 (11A) is in contact with the sealing layer 13B above the partition 6C. In addition, the sealing layer SE11 is in contact with the sealing layer SE12 provided on the dummy subpixel DP2 above the partition 6A.

In other words, the sealing layer SE11 is not separated from the other sealing layers SE12 and 13B arranged in the first direction X. In the present embodiment, the boundary B3 is formed in a straight line. In such a case, the extending portion 131b of the sealing layer 13B is formed in a straight line along the second direction Y.

The same advantages as those of each of the above-described embodiments can also be obtained in the present embodiment.

An example of applying the configuration of the present embodiment to the other position on the display device DSP will be described.

FIG. 19 is a schematic plan view showing an enlarged area surrounded by frame XIX in FIG. 5. The area surrounded by the frame XIX corresponds to, for example, a part of the upper side of a circular display device DSP.

As shown in FIG. 19, the sealing layer 11A is provided on the dummy subpixels DP1 and DP3 of the dummy pixel DPA. Focus on the outer circumferential area OP will be made here. The sealing layer 11A is in contact with the sealing layer 13B. In addition, the sealing layer 13B is also in contact with the sealing layer SE12 provided on the dummy pixel DPA. In the area shown in FIG. 19, the sealing layer 13B provided in the outer circumferential area OP is not separated from the sealing layers SE11 and SE12 provided in the dummy pixel region DMY.

Incidentally, as shown in FIG. 19, the partition 6 may include connecting portions CT which connect partitions 6 divided by slits SL. The connecting portions CT are arranged at predetermined intervals in the second direction Y. Incidentally, the arrangement of the connection portions CT is not limited to the example shown in FIG. 19.

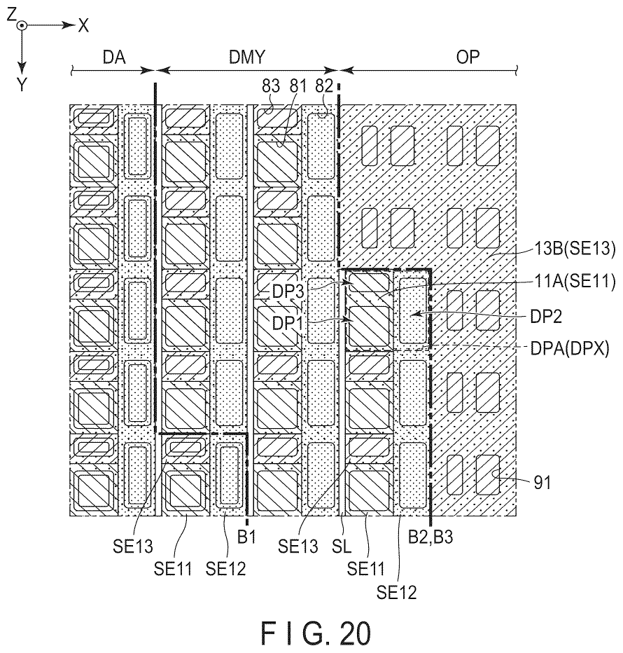

FIG. 20 is a schematic plan view showing an enlarged area surrounded by frame XX in FIG. 5. The area surrounded by the frame XX corresponds to, for example, a part of the right side of a circular display device DSP.

In FIG. 20, focus on the dummy pixels DPA located at the bent area (bend point) along the stair-stepped boundary B2 will be made. The sealing layer 11A is provided on the dummy subpixels DP1 and DP3.

This sealing layer 11A is in contact with the sealing layer 13B. In addition, the sealing layer 13B is also in contact with the sealing layer SE12 provided on the dummy pixel DPA. In the area shown in FIG. 20, the sealing layer 13B provided in the outer circumferential area OP is not separated from the sealing layers 11A and SE12 arranged in the second direction Y or the sealing layer SE12 arranged in the first direction X.

In the example shown in FIG. 19 and FIG. 20, the sealing layers SE11 and SE12 provided on the dummy pixel DPA and the sealing layer SE13 provided in the outer circumferential area OP are also in contact with each other above the partition 6. The impregnation of the etchant into the outer circumferential area OP can be suppressed by bringing these end portions into contact with each other.

In addition, the slit SL is formed on the side of the dummy pixel DPA. When the end portion of the sealing layer provided on the dummy subpixel DP3 of the dummy pixel DPA overlaps with the slit SL, there is a risk that the etchant may impregnate from the slit SL into the dummy subpixel DP3.

As shown in the examples of FIG. 19 and FIG. 20, by providing a sealing layer different from the sealing layer SE13 provided in the outer circumferential area OP, on the dummy subpixel DP3, the impregnation of the etchant from the slit SL into the peripheral region OP via the dummy subpixel DP3 can be suppressed. As a result, undesired loss of the stacked film FL3 provided on the partition 6C can be suppressed, and degradation in appearance is suppressed.

In the present embodiment, the organic layer OR1 is an example of a first organic layer, the organic layer OR3 is an example of a second organic layer, the stacked film FL1 is an example of a first stacked film, the stacked film FL3 is an example of a second stacked film, the dummy subpixel DP1 of the dummy pixel DPA is an example of a first dummy subpixel, the dummy subpixel DP3 of the dummy pixel DPA is an example of a second dummy subpixel, the sealing layer SE11 is an example of a first sealing layer, and the sealing layer SE13 is an example of a second sealing layer.

Incidentally, the configurations of the above-described first to third embodiments are applied to at least one of the plurality of dummy pixels DPA in the dummy pixel area DMY. For example, the configurations may be applied to parts of the plurality of dummy pixels DPA in the dummy pixel area DMY or all of the plurality of dummy pixels DPA.

In addition, one of the configurations of the above-described first to third embodiments may be applied to a single display device or two or more different configurations may be applied to a single display device depending on the position of the dummy pixel area DMY. In addition, the connecting portion CT of the partition 6 shown in FIG. 19 is applicable to the other of the above-described embodiments.

### Fourth Embodiment

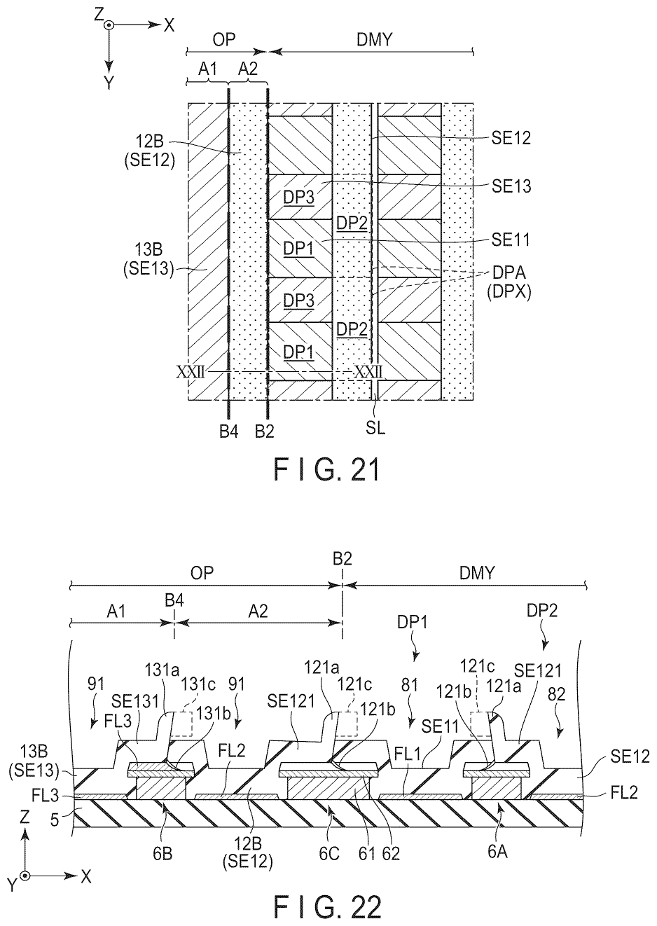

FIG. 21 is a schematic plan view showing a display device DSP according to the present embodiment. In FIG. 21, focus on sealing layers SE11, SE12, and SE13 is mainly made and the other elements are omitted.

As shown in FIG. 21, an outer circumferential area OP includes an area A1 and an area A2. A boundary between the area A1 and the area A2 is defined as a boundary B4. The area A1 surrounds a dummy pixel area DMY, and the area A2 is formed between the dummy pixel area DMY and the area A1.

For example, the area A2 surrounds the dummy pixel area DMY, and the area A1 surrounds the area A2. In other words, the area A1 surrounds the dummy pixel area DMY from a position outside the area A2. A sealing layer provided in the area A2 is different from a sealing layer provided in the area A1.

A sealing layer SE13 is provided in the area A1, and a sealing layer SE12 is provided in the area A2. In other words, a plurality of sealing layers (sealing layers SE12 and SE13) are provided in the outer circumferential area OP. The sealing layer SE12 provided in the area A2 is referred to as a sealing layer 12B.

The sealing layer provided in the area A2 is not separated from the sealing layer provided in the dummy pixel region DMY or the sealing layer provided in the outer circumferential area OP. Focus on the boundary B2 will be made here. The sealing layer 12B is in contact with the sealing layer SE11 provided on the dummy subpixel DP1 and is in contact with the sealing layer SE13 provided on the dummy subpixel DP3, above the partition 6 which is located between the dummy pixel area DMY and the outer circumferential area OP.

Focus on the boundary B4 will be made here. The sealing layer 12B is in contact with the sealing layer 13B provided in the area A1 above the partition 6 which is located between the area A1 and the area A2. In other words, the sealing layer 12B is not separated from the other sealing layers SE11 and SE13 arranged in the first direction X.

FIG. 22 is a schematic cross-sectional view showing the dummy pixel area DMY and the outer circumferential area OP along XXII-XXII line in FIG. 21. In this figure, the substrate 10, the circuit layer 11, the organic insulating layer 12, the sealing layer SE2, and the resin layers RS1 and RS2 are omitted.

End portions of the sealing layers SE11 and SE12B are in contact with each other on the partition 6C. The sealing layer SE12 includes an overlapping portion SE121 located above the partition 6C. The overlapping portion SE121 is in contact with the end portion of the sealing layer SE11. Similarly, the overlapping portion SE121 is also in contact with the end portion of the sealing layer SE13 provided on the dummy subpixel DP3.

The overlapping portion SE121 may include a protruding portion 121a that protrudes upwardly. The protruding portion 121a is provided at a position higher than the sealing layer SE11, above the partition 6C. In addition, the overlapping portion SE121 may further include an extending portion 121b extending toward a gap formed between the sealing layer SE11 and the upper portion 62 of the partition 6C.

In addition, the protruding portion 121a of the sealing layer SE12 may overlap with the sealing layer SE11. More specifically, the protruding portion 121a may include a portion 121c (represented by a dashed line in FIG. 22) which overlaps with the sealing layer SE11. In this case, the partition 6C, the sealing layer SE11, and the protruding portion 121a of the sealing layer SE12 are arranged in this order, in the third direction Z.

The sealing layer SE13 includes an overlapping portion SE131 located above the partition 6B located between the area A1 and the area A2. The overlapping portion SE131 is in contact with the end portion of the sealing layer SE12 (sealing layer 12B) above the partition 6B. The overlapping portion SE131 may include a protruding portion 131a that protrudes upwardly. The protruding portion 131a is provided at a position higher than the sealing layer SE12, above the partition 6B.

In addition, the overlapping portion SE131 may further include an extending portion 131b extending toward a gap formed between the sealing layer SE12 and the upper portion 62 of the partition 6B. A stacked film FL3 is provided between the partition 6B and the overlapping portion SE131. The stacked film FL3 is surrounded by the partition 6B, the overlapping portion SE131, and the protruding portion 131b.

In addition, the protruding portion 131a of the sealing layer SE13 may overlap with the sealing layer SE12. More specifically, the protruding portion 131a may include a protruding portion 131c (represented by a dashed line in FIG. 22) which overlaps with the sealing layer SE12. In this case, the partition 6B, the sealing layer SE12, and the protruding portion 131a of the sealing layer SE13 are arranged in this order, in the third direction Z.

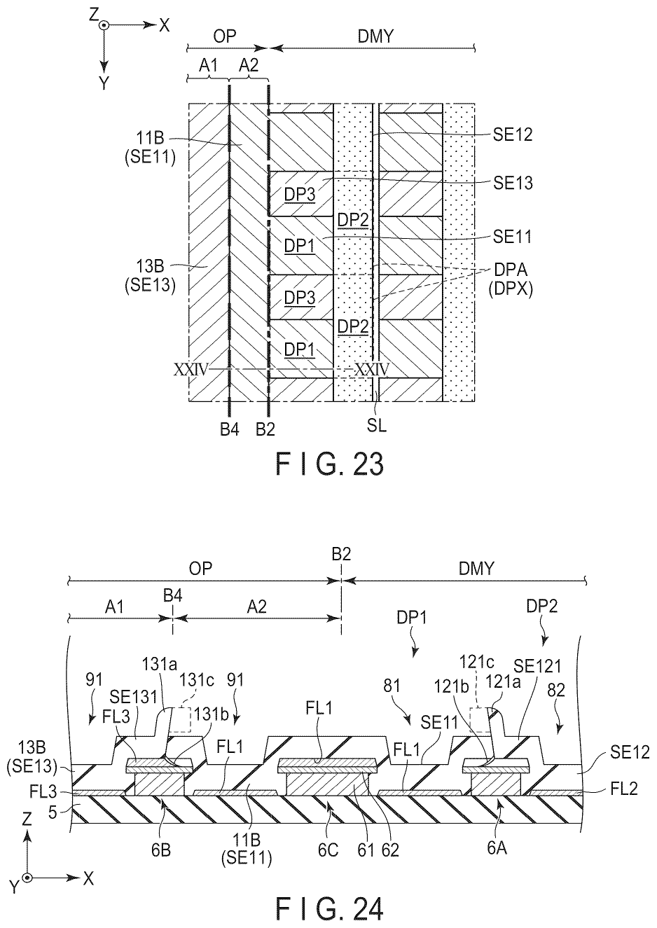

FIG. 23 is a schematic plan view showing another example of the display device DSP according to the present embodiment. In FIG. 23, a configuration of an area A2 is different from the example shown in FIG. 21.

The sealing layer SE11 is provided in the area A2. The sealing layer SE11 provided in the area A2 is hereinafter referred to as a sealing layer 11B. In other words, a plurality of sealing layers (sealing layers SE11 and SE13) are provided in the outer circumferential area OP.

The sealing layer 11B is formed continuously with the sealing layer SE11 provided on the dummy subpixel DP1 of the dummy pixel DPA. In other words, the sealing layer 11B is connected to the sealing layer SE11 provided on the dummy subpixel DP1 of the dummy pixel DPA.

Focus on the boundary B2 will be made here. The sealing layer 11B is in contact with the sealing layer SE13 provided on the dummy subpixel DP3 above the partition 6 which is located between the dummy pixel area DMY and the outer circumferential area OP. Focus on the boundary B4 will be made here. The sealing layer 11B is in contact with the sealing layer 13B provided in the area A1 above the partition 6 which is located between the area A1 and the area A2.

FIG. 24 is a schematic cross-sectional view showing the dummy pixel area DMY and the outer circumferential area OP along XXIV-XXIV line in FIG. 23. In this figure, the substrate 10, the circuit layer 11, the organic insulating layer 12, the sealing layer SE2, and the resin layers RS1 and RS2 are omitted.

As shown in FIG. 24, the sealing layer SE11 including the sealing layer 11B continuously covers the partition 6A, a part of the partition 6B, and the partition 6C.

Focus on the sealing layer SE13 will be made here. The sealing layer SE13 includes an overlapping portion SE131 located above the partition 6B. The overlapping portion SE131 is in contact with the end portion of the sealing layer SE11. The overlapping portion SE131 may include a protruding portion 131a that protrudes upwardly. The protruding portion 131a is provided at a position higher than the sealing layer SE11, above the partition 6B.

In addition, the overlapping portion SE131 may further include an extending portion 131b extending toward a gap formed between the sealing layer SE11 and the upper portion 62 of the partition 6B. A stacked film FL3 is provided between the partition 6B and the overlapping portion SE131.

In addition, the protruding portion 131a of the sealing layer SE13 may overlap with the sealing layer SE11. More specifically, the protruding portion 131a may include a protruding portion 131c (represented by a dashed line in FIG. 24) which overlaps with the sealing layer SE11. In this case, the partition 6B, the sealing layer SE11, and the protruding portion 131a of the sealing layer SE13 are arranged in this order, in the third direction Z. Incidentally, in the example shown in FIG. 24, the stacked film FL1 is provided on the partition 6C, but the stacked film FL1 may be lost.

Even in the configuration of the present embodiment, the same advantages as those of the first embodiment can also be obtained. More specifically, end portions of the sealing layer provided in the area A1 and the sealing layer provided in the area A2 are in contact with each other above the partition 6. Impregnation of the etchant from the upper side can be suppressed and the stacked film FL3 can be left above the partition 6, by the end portions of the sealing layers in contact with each other above the partition 6.

Furthermore, in the present embodiment, an extending portion 131b (shown in FIG. 22 and FIG. 24) can be formed linearly along a boundary B4. By forming the protruding portion 131b linearly, the impregnation of the etchant from the upper side can be further suppressed.

An example of applying the configuration of the present embodiment to the other position on the display device DSP will be described.

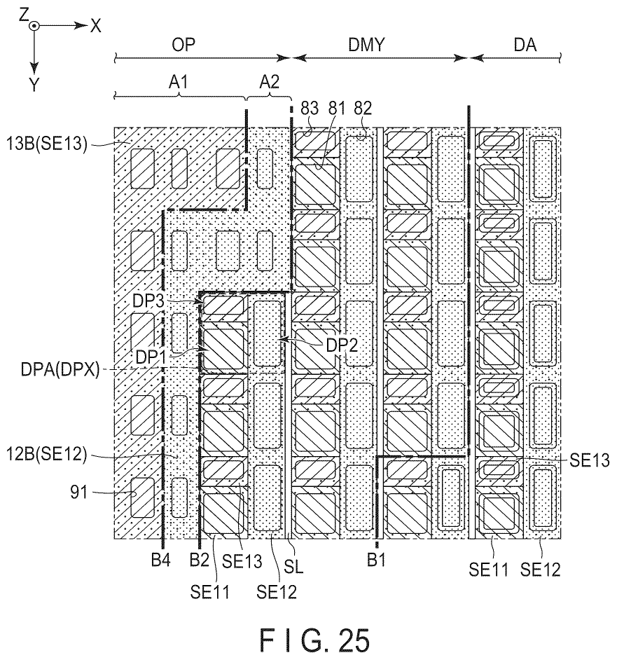

FIG. 25 is a schematic plan view showing an enlarged area surrounded by frame XXV in FIG. 5. The area surrounded by frame XXV corresponds to, for example, a portion of the left side of a circular display device DSP.

In the example of FIG. 25, a sealing layer 13B is provided in the area A1, and a sealing layer 12B is provided in the area A2. The sealing layer 12B is in contact with the sealing layers SE11 and SE13 on the dummy pixel DPA.

In addition, a part of the sealing layer 12B is connected to the sealing layer SE12 provided on the dummy subpixel DP2 of the dummy pixel DPA located at the bent area (bend point) at the stair-stepped boundary B2, in the second direction Y. Furthermore, the sealing layer 12B is in contact with the sealing layer 13B provided in the area A1.

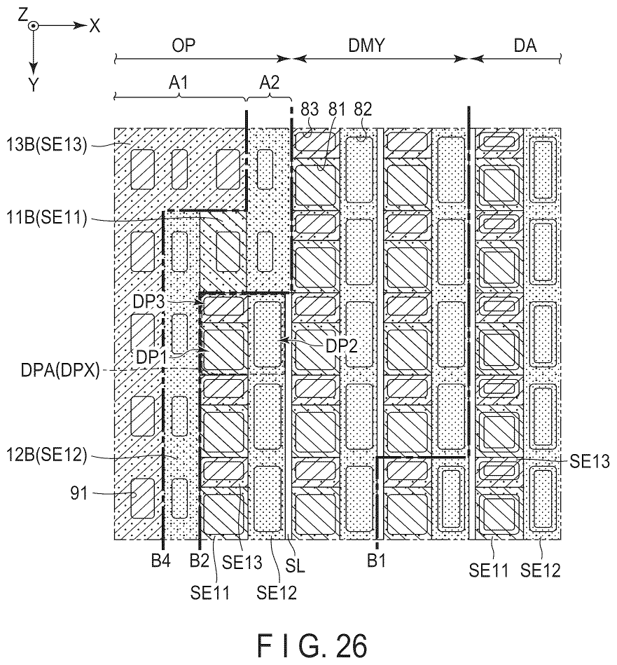

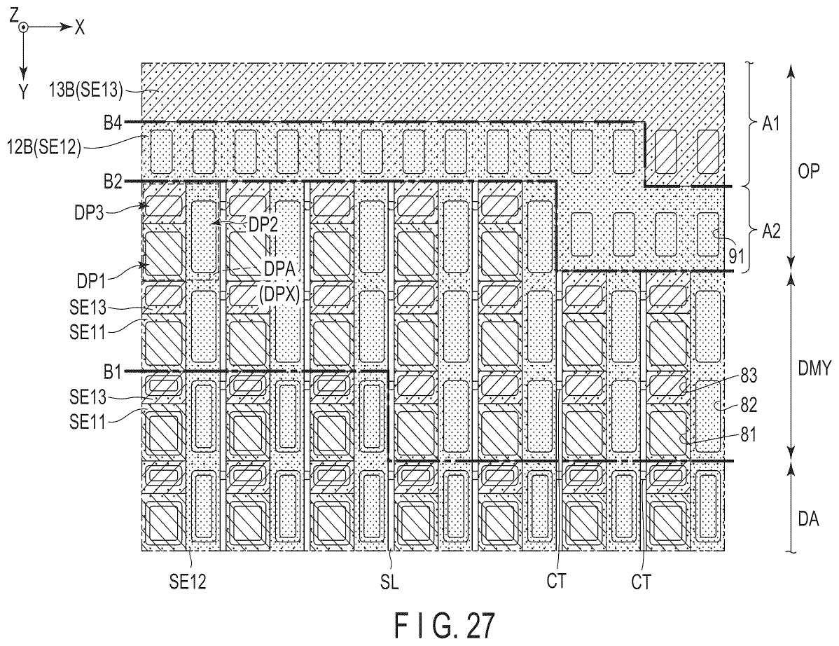

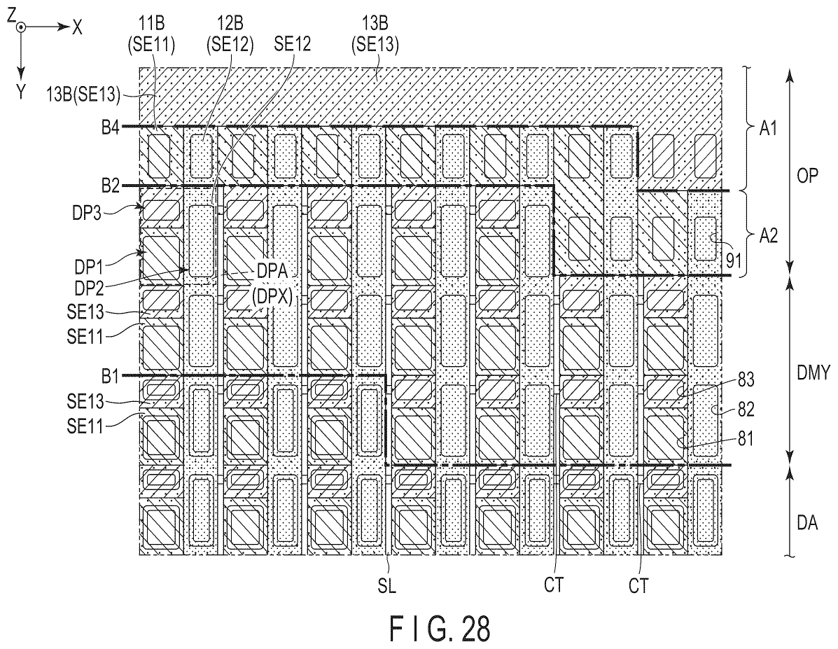

FIG. 26 is a schematic plan view showing another example of the display device DSP. In the example shown in FIG. 26, unlike the example in FIG. 25, the sealing layer 11B is provided in the area A2 above the dummy pixel DPA. Incidentally, in the example of FIG. 25, an example where the sealing layer 12B is provided in the area A2 has been disclosed. However, the sealing layer 11B may also be provided in the area A2.

FIG. 27 is a schematic plan view showing an enlarged area surrounded by frame XXVII in FIG. 5. In the example of FIG. 27, a sealing layer 13B is provided in the area A1, and a sealing layer 12B is provided in the area A2.

The sealing layer 12B is in contact with the sealing layer SE13 provided on the dummy subpixel DP3 of the dummy pixel DPA. In addition, the sealing layer 12B connects to the sealing layer SE12 provided on the dummy subpixel DP2 of the dummy pixel DPA in the second direction Y. Furthermore, the sealing layer 12B is in contact with the sealing layer 13B provided in the area A1.

In the example of FIG. 27, an example where the sealing layer 12B is provided in the area A2 has been disclosed. However, the sealing layer 11B may also be provided in the area A2.

FIG. 28 is a schematic plan view showing another example of the display device DSP. In the example shown in FIG. 28, unlike the example in FIG. 27, the sealing layer 11B and the sealing layer 12B are alternately provided in the first direction X, in the area A2. These sealing layers 11B and 12B are in contact with each other in the first direction X.

The sealing layer 11B is in contact with the sealing layer SE13 provided on the dummy subpixel DP3 of the dummy pixel DPA. The sealing layer 12B connects to the sealing layer SE12 provided on the dummy subpixel DP2 of the dummy pixel DPA in the second direction Y.

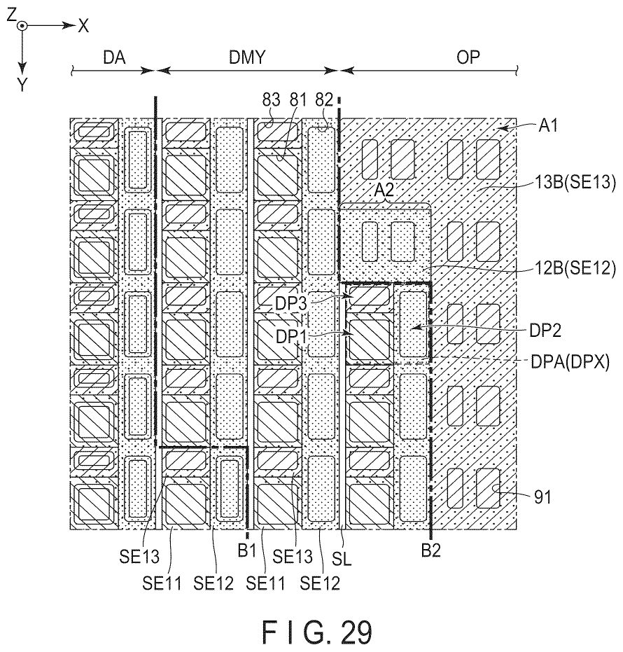

FIG. 29 is a schematic plan view showing an enlarged area surrounded by frame XXIX in FIG. 5. In the example shown in FIG. 29, an area A2 is formed above the dummy pixel DPA located in a bent area (bent point) of a boundary B2.

The area A2 is arranged with this dummy pixel DPA in the second direction Y. The sealing layer SE12B is provided in the area A2. The sealing layer 12B connects to the sealing layer SE12 provided on the dummy subpixel DP2 of the dummy pixel DPA in the second direction Y. Furthermore, the sealing layer 12B is in contact with the sealing layer 13B provided in the area A1.

In the example of FIG. 29, an example where the sealing layer 12B is provided in the area A2 has been disclosed. However, the sealing layer 11B may also be provided in the area A2.

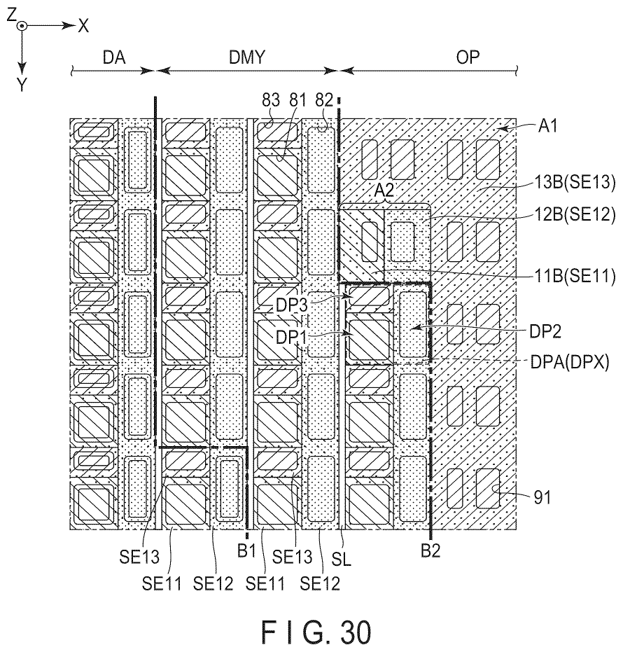

FIG. 30 is a schematic plan view showing another example of the display device DSP. In the example shown in FIG. 30, unlike the example in FIG. 29, the sealing layer 11B is provided to be adjacent to the sealing layer 12B in the first direction X, in the area A2. These sealing layers 11B and 12B are in contact with each other. The sealing layer 11B is in contact with the sealing layer 13B provided in the area A1.

In the example of FIG. 21 in the present embodiment, the organic layer OR2 is an example of a first organic layer, the organic layer OR3 is an example of a second organic layer, the stacked film FL2 is an example of a first stacked film, the stacked film FL3 is an example of a second stacked film, the dummy subpixel DP2 of the dummy pixel DPA is an example of a first dummy subpixel, the dummy subpixel DP3 of the dummy pixel DPA is an example of a second dummy subpixel, the sealing layer SE12 is an example of a first sealing layer, the sealing layer SE13 is an example of a second sealing layer, the area A1 is an example of a first area, and the area A2 is an example of a second area.

In the example of FIG. 22 in the present embodiment, the organic layer OR1 is an example of a first organic layer, the organic layer OR3 is an example of a second organic layer, the stacked film FL1 is an example of a first stacked film, the stacked film FL3 is an example of a second stacked film, the dummy subpixel DP1 of the dummy pixel DPA is an example of a first dummy subpixel, the dummy subpixel DP3 of the dummy pixel DPA is an example of a second dummy subpixel, the sealing layer SE11 is an example of a first sealing layer, the sealing layer SE13 is an example of a second sealing layer, the area A1 is an example of a first area, and the area A2 is an example of a second area.

Incidentally, each configuration of the present embodiment may be applied to several areas of the outer circumferential area OP or to the entire circumference of the outer circumferential area OP.

According to the display device DSP configured as described above, the yield can be improved. In addition, various desirable effects can be obtained from each of the above-described embodiments.

All of the display devices that can be implemented by a person of ordinary skill in the art through arbitrary design changes to the display device described above as the embodiment of the present invention come within the scope of the present invention as long as they are in keeping with the spirit of the present invention. Various modified examples which may be conceived by a person of ordinary skill in the art in the scope of the idea of the present invention will also fall within the scope of the invention. For example, even if a person of ordinary skill in the art arbitrarily modifies each of the above embodiments by adding or deleting a structural element or changing the design of a structural element, or adding or omitting a step or changing the condition of a step, all of the modifications fall within the scope of the present invention as long as they are in keeping with the spirit of the invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device comprising:
a display area including a plurality of pixels displaying an image;
a dummy pixel area which includes a plurality of dummy pixels each including a first dummy subpixel not displaying an image and which surrounds the display area;
an outer circumferential area surrounding the dummy pixel area;
a partition provided in the display area, the dummy pixel area, and the outer circumferential area and including a conductive lower portion and an upper portion having an end portion protruding from a side surface of the lower portion;
a first stacked film provided in the first dummy subpixel and including a first organic layer;
a first sealing layer formed of an inorganic insulating material and provided above the first stacked film;
a second stacked film provided in the outer circumferential area and including a second organic layer; and
a second sealing layer formed of an inorganic insulating material and provided above the second stacked film, wherein
the partition is formed continuously from the dummy pixel area to the outer circumferential area.

2. The display device of claim 1, wherein
the second organic layer includes a same light emitting layer as a light emitting layer of the first organic layer, and
the second sealing layer is formed continuously with the first sealing layer, at a position above the partition located between the dummy pixel area and the outer circumferential area.

3. The display device of claim 2, wherein
the first sealing layer and the second sealing layer are formed to cover the partition located between the dummy pixel area and the outer circumferential area.

4. The display device of claim 3, further comprising:
a third sealing layer, wherein
the dummy pixel further includes a second dummy subpixel,
a third stacked film including a third organic layer including a light emitting layer different from the light emitting layer of the first organic layer is provided in the second dummy subpixel, and
the third sealing layer is provided above the third stacked film and is in contact with each of the first sealing layer and the second sealing layer.

5. The display device of claim 2, wherein
the dummy pixel further includes a second dummy subpixel where the first stacked film is provided,
the first sealing layer is further provided above the first stacked film provided in the second dummy subpixel, and
both the first sealing layers provided in the first dummy subpixel and the second dummy subpixel are formed continuously with the second sealing layer, above the partition located between the dummy pixel area and the outer circumferential area.

6. The display device of claim 5, wherein
the first sealing layer is provided in the first dummy subpixels and the second dummy subpixels of the at least two adjacent dummy pixels.

7. The display device of claim 1, wherein
the second organic layer includes a light emitting layer different from a light emitting layer of the first organic layer, and
the second sealing layer is in contact with the first sealing layer, above the partition located between the dummy pixel area and the outer circumferential area.

8. The display device of claim 7, wherein
the dummy pixel further includes a second dummy subpixel where the first stacked film is provided,
the first sealing layer is further provided above the first stacked film provided in the second dummy subpixel, and
each of the first sealing layers provided in the first dummy subpixel and the second dummy subpixel is in contact with the second sealing layer, above the partition located between the dummy pixel area and the outer circumferential area.

9. The display device of claim 8, wherein
the first sealing layer is provided in the first dummy subpixels and the second dummy subpixels of the at least two adjacent dummy pixels.

10. The display device of claim 1, wherein
the second sealing layer includes a protruding portion protruding more upwardly than the first sealing layer, above the partition located between the dummy pixel area and the outer circumferential area.

11. The display device of claim 10, wherein
the protruding portion includes a portion overlapping with the first sealing layer.

12. The display device of claim 10, wherein
the second sealing layer further includes an extending portion extending toward a gap formed between the first sealing layer and the partition.

13. The display device of claim 12, wherein
the second stacked film is further provided between the partition, the second sealing layer, and the extending portion located between the dummy pixel area and the outer circumferential area.

14. A display device comprising:
a display area including a plurality of pixels displaying an image;
a dummy pixel area which includes a plurality of dummy pixels each including a first dummy subpixel and a second dummy subpixel not displaying an image and which surrounds the display area;
an outer circumferential area surrounding the dummy pixel area;
a partition provided in the display area, the dummy pixel area, and the outer circumferential area and including a conductive lower portion and an upper portion having an end portion protruding from a side surface of the lower portion;
a first stacked film provided in the first dummy subpixel and including a first organic layer;
a first sealing layer formed of an inorganic insulating material and provided above the first stacked film;
a second stacked film provided in the second dummy subpixel and including a second organic layer including a light emitting layer different from a light emitting layer of the first organic layer; and
a second sealing layer formed of an inorganic insulating material and provided above the second stacked film, wherein
the partition is formed continuously from the dummy pixel area to the outer circumferential area,
the outer circumferential area includes a first area surrounding the dummy pixel area, and a second area provided between the first area and the dummy pixel area,
the second sealing layer is further provided in the first area,
the first sealing layer is further provided in the second area, and
the first sealing layer provided in the second area is in contact with the second sealing layer provided in the first area, above the partition located between the first area and the second area.

15. The display device of claim 14, wherein
the first sealing layer provided in the second area is further in contact with the second sealing layer provided in the second dummy subpixel, above the partition located between the dummy pixel area and the outer circumferential area.

16. The display device of claim 15, wherein
the first sealing layer provided in the second area is formed continuously with the first sealing layer provided in the first dummy subpixel.

17. The display device of claim 14, wherein
the second sealing layer includes a protruding portion protruding more upwardly than the first sealing layer, above the partition located between the first area and the second area.

18. The display device of claim 17, wherein
the protruding portion includes a portion overlapping with the first sealing layer.

19. The display device of claim 17, wherein
the second sealing layer further includes an extending portion extending toward a gap formed between the first sealing layer and the partition.

20. The display device of claim 19, wherein
the second stacked film is further provided between the partition, the second sealing layer, and the extending portion, the partition being located between the first area and the second area.
